(19) United States
(12) Patent Application Publication
(10) Pub. No.: US 2022/0340274 A1
(43) Pub. Date: Oct. 27, 2022

(54) REMOTE DEPLOYABLE TRANSIENT SENSORY KIT

(71) Applicant: Joulea LLC, Atlanta, GA (US)

(72) Inventors: Ramtin Motahar, Atlanta, GA (US); Rosanna Beron, Atlanta, GA (US); Simon Ignacio Briceno, Atlanta, GA (US)

(21) Appl. No.: 17/240,983

(22) Filed: Apr. 26, 2021

(51) Int. Cl. B64C 39/02; H04Q 9/00; B64D 41/00; G08G 5/00; G01R 21/133; G05D 1/10

(52) U.S. Cl. CPC B64C 39/024; H04Q 9/00; B64D 41/00; G08G 5/0034; G08G 5/0069; G01R 21/133; G05D 1/101; H04Q 2209/40; B64C 2201/027; B64C 2201/042; B64C 2201/146

(57) ABSTRACT

Embodiments describe a remote deployable transient sensory kit comprising a shipping container having a remote deployable transient sensory system. The sensory system includes a controller, a set of batteries configured according to a flight plan optimization associated with a building energy modeling mission, and a mobile device for wireless communication with the remote deployable transient sensory system. The mobile device includes a processor, a computer-readable memory comprising an application executable via the processor for collecting energy usage data and building characteristics via the remote deployable transient sensory system, and a transceiver configured for wireless communication with the remote deployable transient sensory system.

### TECHNICAL FIELD

The present disclosure relates to a system and method for providing a remote deployable transient sensory kit usable for improving a built environment design, construction and operation. More specifically, this disclosure relates to a system and method for active monitoring and energy usage quantification associated with a built environment during construction and post-occupancy using an aerial remote deployable transient sensory system kit.

### BACKGROUND

Cities, towns, businesses and individuals seek out ways to be more sustainable. Most sustainability initiatives target a reduction in the use of energy or other resources. For most initiatives, the first step requires an understanding of where waste is occurring, and for large projects this is often a resource use study or energy consumption study. While energy consumption studies look at the ultimate resource use of the built environment, most prefer an immediate solution to reduce energy consumption for the party commissioning the study. Large scale evaluations, such as the one conducted in 2016 by Siemens in San Francisco using their City Performance Tool (CyPT), may evaluate resource use across a city and look for ways to improve energy consumption. This type of large-scale resource evaluation often guides a cost benefit analysis of immediate versus long term changes to reduce energy consumption.

Until recently, the energy performance gap between modelled resource use and actual operational use was difficult to monitor because of the siloed nature of the industry. In other circumstances, the performance gap may be difficult to comprehend once modelled. Recent developments in automated building meters and other monitoring devices have improved identification and comprehension of the energy performance gap for owners and building operators.

Resource analysis for new construction is generally accomplished using building energy models (BEMs). BEMs are computer generated models that are used to predict the post-occupancy resource usage of the built physical environment. BEMs such as EnergyPlus®, Integrated Environmental Solutions® (IES) and eQuest®, are computer-based software building simulation tools that focus on resource consumption, utility bills and energy costs of various resource related items such as heating, ventilation and air conditioning (HVAC), lighting and water consumption. While these models may address more than energy, they are nonetheless typically referred to as energy models.

A typical energy model has inputs for location data such as physical geographical location, weather conditions, building orientation and other pertinent site features; building envelope, such as air infiltration goals, area orientation, glazing, solar absorbance and visible light transmittance; internal gains such as lighting, plug loads, sensible and latent loads from occupants; schedules such as occupancy data; and various types of energy systems such as water heating systems, alternative energy types such solar and wind, types of space heating, cooling, ventilating, fan and pump types and other aspects of HVAC.

BEMs have been available in the Architectural, Engineering, Construction & Operation (“AECO”) industry for many years, but they are often underutilized. BEMs are most often used near the end of the design phase to verify that the designed built environment will have the desired post-occupancy resource footprint once built. Outside of high-performance built environments or buildings seeking certifications such as Leadership in Energy and Environmental Design (LEED), Living Building Challenge, etc., BEMs are seldom considered past the initial design phase to guide design. Furthermore, the need to estimate the inputs and parameters employed by the BEMs creates discrepancies between the predicted and the actual resource performance.

Consequently, each of the (1) design, (2) construction and (3) operation phases are currently executed without an accurate reference basis (i.e., data and models), leading to discrepancies between the initial estimates of the built environment resource usage in the design phase and actual operation of the built environment post construction. These discrepancies from the BEMs can often be on the order of 20% to 50% less than actual post occupancy resource use. The sustainable commercial building community has recognized this problem. Consequently, standards such as LEED v4 and Living Building Challenge 4.0 are adding emphasis on commercial building post-occupancy performance verification. Unfortunately, these types of built environments are a small subset of new construction projects and an even smaller subset of the building stock and so these discrepancies continue to exist.

Along with underutilization of BEMs, the construction industry has been slow to adopt other technologies for reducing energy costs, which has resulted in continued energy inefficiencies. Currently, individual software packages are used throughout each phase of development including design, construction and operation. The industry belief has been that the number and divergent nature of the professionals and processes involved with the development of a large built environment project make it impossible for a single system to coordinate and facilitate all aspects of design and construction. This lack of continuity between the various stages of design, construction and operation stands as a significant hurdle to achieving a coordinated approach to reducing energy costs. Rarely does a post-occupancy review of the operation of a building yield the best resource usage for that built environment. In post-occupancy energy analysis, after the construction is complete, the best available energy profile will necessarily include design or construction flaws that already exist. For many years, no attempts were made to improve building efficiency by coordinating the design, construction and operation of a building into a single cohesive system.

Only recently has anyone attempted to articulate a system that links the design phase and the construction phase of the built environment. Google® discloses a computer implemented system to coordinate the design and construction of a structure. Their system is described in published U.S. Application No. 2012/0296611 and in U.S. Pat. Nos. 8,229,715; 8,285,521; 8,516,572; 8,843,352 and 8,954,297 and has been assigned to a new company, Flux; however, Flux's commercial end-to-end data sharing system has been discontinued. These patents, which are incorporated herein by reference, describe many of the steps and requirements for designing and constructing a built environment.

Likewise, IES, a maker of energy modeling software, recently began a research and development initiative using operational data from some of their BEMs to improve the post-occupancy evaluation efficiency of buildings modeled using their BEM software. This effort is described in the present disclosure as a continuously calibrated BEM. IES has a proprietary system that imports and incorporates data from a handful of constructed buildings using their BEMs back into their modeling platform and provides analysis of problem areas in the construction and operation of these buildings. This IES research and development initiative is limited, since it only collects feedback from certain buildings whose owners were willing to share the costs of the initiative, and it then only uses that collected information to impact the design of another building that is deemed to have sufficient similar benchmarks, i.e., similar size, similar use, similar location type, etc.

Currently no avenue exists for using available resource studies or other operational data to generate substantial improvements in the way that new structures are designed or built. The construction industry has lagged behind other industries in adopting technologies that could improve efficiency. Therefore, there seems to be a big disconnect between gathering post-occupancy operational information and incorporating that information back into the design and/or construction phases of a built environment to accomplish long term resource reduction. Moreover, without a centralized aggregation system, current technologies focus only on disjointed analyses of energy usage without a coordinated and centralized way to identify, track and calibrate real-world energy usage information with correlated design choices, materials information and deviation reporting that identifies changes and alterations from the engineered design.

The system as described herein, referred to as JOULEA™ (Justified Operational Use of Lifecycle Energy Application), is designed to generate, compile and analyze continuous information on resource use and provide feedback on ways to improve resource use in the immediate built environment using, among other tools, continuously calibrated BEMs. U.S. Patent Application No. 2019/030494, incorporated herein by reference, describes aspects of the energy model calibration system 100. The system obtains building efficiency data using a deployable transient sensory system which compiles virgin data, i.e., complete design, construction and operations data from newly built environments, as well as aftermarket data, e.g., design BEMs, and/or operational resource information for other existing built environments. This information is collected into a single system that can work cooperatively with the software that is already being used in the architecture, engineering, construction and operations (AECO) community. The operations data may be generated, in part, as sensory energy data output using a system of sensors placed at key points in the built environment. In new construction, the sensors can be installed as part of the planning of the original construction drawings during the design phase. For existing buildings and structures, the sensory energy data system can be added to the built environment to collect ongoing design and/or construction information, which may be input into JOULEA in conjunction with or in lieu of a conventional BEM, to capture real-time continuous energy usage data associated with post-occupancy-built environment use. While the name JOULEA will be used for ease herein when referencing this system, it is merely a name that does not impact the underlying system technology and could be changed.

The system as described can amass data from varied buildings and/or built environments, as well as design and construction projects without being limited by either the hardware or software (collectively referred to as “the platform”) that is being used or is intended to be used. Specifically, the platform attaches to the raw data that is sensed by the system, either through hardware (through sensors or other monitors, i.e., transient sensing systems) or software (through the use of software plug-ins). The current system, JOULEA, collects data from disparate sources and can use any data management platform or master data management tool to normalize the data regardless of the development platform. The system uses an optimization engine to look for a variety of features including but not limited to, deficiencies or performance gaps that result from either design or construction, system faults during operation and maintenance during post-occupancy, enhancements or improvements in resource use, and patterns indicative of building lifecycles, i.e., resource use over time.

In some aspects, the described system may crowdsource information from a plurality of built environment locations to build an aggregated database that contains building operation characteristics, system characteristics and real-time energy usage data indicative of how and when energy is used, and indications of energy usage anomalies that lie outside of observed usage thresholds. The outputs of the optimization methods and engine are correlated and used to direct new built environment designs, constructions or operations and provide real-time feedback and recommendations to the appropriate platforms so that the design team and/or construction team can use those recommendations to immediately influence their choices. Particularly in large commercial construction, design and material selections can have significant impacts on the resource usage, embodied carbon and operations of a building. Once implementation of those selections begins in the construction phase, changes to improve long term resource use can become cost prohibitive. The system as described herein can overlay existing design, construction and/or operational platforms, thereby allowing it to coordinate the information flowing from the varied systems and provide immediate feedback to the individual platforms where appropriate, in order to timely facilitate improvements in design, construction and/or resource usage during operation.

In other aspects, the collection of such data has been labor-intensive, requiring many human hours for the data collection and analysis. For built environments having an existing BEM, many of the quantifiable parameters needed as inputs may be available. However, in most cases, BEMs may not exist for older buildings, and must be first built using research, measurement of energy usage and loss, and using building design plans that may or may not be readily available. Conventional processes and systems for generating calibrated building energy models in post-occupancy routinely take hundreds of human work hours, and several weeks, if not more, to generate the computer models. It is therefore advantageous to provide a remote deployable transient sensory system, that may be enabled with remote sensory systems, autonomous control mechanisms and programming, artificial intelligence engines trained to collect building construction data, building energy usage data, mechanical equipment identification and many other variables used in constructing the continuously calibrated BEM.

This system can improve design, construction and subsequent operating efficiency of a built environment, thereby closing the existing gaps between the design of the BEM and the actual post-occupancy performance of the built environment. The use of transient sensory systems allows the collection of relevant data during construction and post-occupancy, making feedback available to designers, owners and contractors in real time regarding the energy efficiency impact of design and construction decisions. In addition, by collecting much more data during construction, post-occupancy resource issues may be better aligned with their intended designs than issues related to construction. Finally, by collecting divergent data, the system takes advantage of resource efficiencies or expertise developed in one built environment for the optimization of another type of built environment.

It is with respect to these and other considerations that the disclosure made herein is presented.

### BRIEF DESCRIPTION OF THE DRAWINGS

The detailed description is set forth with reference to the accompanying drawings. The use of the same reference numerals may indicate similar or identical items. Various embodiments may utilize elements and/or components other than those illustrated in the drawings, and some elements and/or components may not be present in various embodiments. Elements and/or components in the figures are not necessarily drawn to scale. Throughout this disclosure, depending on the context, singular and plural terminology may be used interchangeably.

FIG. 1 is a block diagram of an energy model calibration system according to embodiments of the present disclosure.

FIG. 2 depicts an example computing environment in which the energy model calibration system may operate according to embodiments of the present disclosure.

FIG. 3 is a flow diagram illustrating an example method for generating a continuously calibrated building energy model (BEM) using the energy model calibration system of FIG. 1.

FIG. 4 a functional schematic of a coverage path planning system according to embodiments of the present disclosure.

FIG. 5 illustrates an example execution of a coverage flight plan with a remote deployable transient sensory system, and collection of post-occupancy energy usage data according to embodiments of the present disclosure.

FIG. 6 illustrates an exemplary collection of post-occupancy energy usage data using the remote deployable transient sensory system according to embodiments of the present disclosure.

FIG. 7 illustrates collection of post-occupancy energy usage data associated with mechanical equipment using the remote deployable transient sensory system according to embodiments of the present disclosure.

FIG. 8 is another illustration of collection of post-occupancy energy usage data associated with mechanical equipment using the remote deployable transient sensory system according to embodiments of the present disclosure.

FIG. 9 is a flow diagram for an example method for collecting sensory data using a remote deployable transient sensory kit according to embodiments of the present disclosure.

FIG. 10 illustrates collection of building construction data associated with a build site using the remote deployable transient sensory system according to embodiments of the present disclosure.

FIG. 11 depicts collection of building construction data associated with a build site using the remote deployable transient sensory system according to embodiments of the present disclosure.

FIG. 12 depicts a user interface displaying output based on the building construction data according to embodiments of the present disclosure.

FIG. 13 illustrates an example remote deployable transient sensory kit according to embodiments of the present disclosure.

FIG. 14 depicts a functional block diagram of an example remote deployable transient sensory system in accordance with the present disclosure.

### DETAILED DESCRIPTION

### Overview

The systems and methods disclosed herein include a computer-implemented method for generating a continuously calibrated (C²) building energy model (BEM) associated with a built environment utilizing one or more remote deployable transient sensory systems configured as autonomous or semi-autonomous drones. The C² BEM described in the present disclosure is an energy model that is continuously calibrated, meaning that the data associated with the energy model is calibrated continuously at a predetermined period of time such as every 1 second, 5 seconds, 10 seconds, 30 seconds, etc. The method can include receiving, via a processor, from a remote deployable transient sensory system, a sensory dataset indicative of a building envelope feature disposed on an exterior surface of a built environment. The method includes modifying a data structure such as a spreadsheet, or database with information that associates the sensory dataset to a 3-D model of the building envelope feature, determining an energy loss characteristic associated with the building envelope feature based on the point cloud model, and generating the C² BEM based on the 3-D model of the building envelope feature and the sensory dataset. As used herein, a building is referred to generally as a structure in a built environment.

In some embodiments, the C² BEM identifies the building envelope feature and a mitigation recommendation to reduce energy loss associated with the energy loss characteristic.

In one example embodiment, modifying the point cloud model comprises modifying an extant 3-dimensional computer model representing the building envelope feature to include data indicative of exterior surfaces of the built environment, and information that associates the data indicative of exterior surfaces of the built environment with sensory data indicative of the energy loss characteristics.

In an example embodiment, the building envelope feature comprises a heating, ventilation and air conditioning (HVAC) device.

In another example embodiment, the building envelope feature comprises a glazing portion.

In yet another example embodiment, the building envelope feature comprises a building facade portion.

In another example embodiment, the building envelope feature comprises a mechanical sealant portion.

In another example embodiment, the building envelope feature comprises a roof element portion.

In an example embodiment, receiving the sensor dataset comprises receiving the sensor dataset from an aerial unmanned aerial system (UAS).

In an example embodiment, the sensory dataset is obtained via the remote deployable transient sensory system while executing a flight plan proximate to the building envelope.

In yet another example embodiment, the method may further include receiving a flight plan from a coverage path planning system.

In another example embodiment of the present disclosure, the method includes receiving the travel path, from a coverage path planning system, wherein the travel path is indicative of a plurality of waypoints associated with the building envelope feature. The flight plan comprises instructions that having travel path instructions for an aerial unmanned aerial system (UAS) that, when executed, causes the UAS to navigate to the plurality of associated waypoints.

According to another example embodiment, generating, via the coverage path planning system, the flight plan, the generating includes identifying, via an artificial intelligence (AI) engine, a candidate source cause of the energy loss characteristic, generating a mathematical optimization model solution to dispatch and control the UAS to a plurality of locations proximate to the plurality of waypoints, wherein the plurality of locations proximate to the plurality of waypoints are associated with the candidate source cause of the energy loss characteristic, and updating the flight travel path with instructions that, when executed by the UAS, control the UAS to fly to the plurality of locations proximate to the plurality of associated waypoints.

In an example embodiment, the travel path, when executed by the UAS, causes the UAS to minimize a total flight time required to fly proximate to the plurality of locations proximate to the plurality of associated waypoints.

In another example embodiment, the travel path, when executed by the UAS, causes the UAS to minimize a count of trajectory changes.

These and other advantages of the present disclosure are provided in greater detail herein.

### Illustrative Embodiments

The disclosure will be described more fully hereinafter with reference to the accompanying drawings, in which example embodiments of the disclosure are shown, and not intended to be limiting.

Presently, there are concerns that built environments in the United States underperform in terms of energy efficiency when compared with their original design documents. The U.S. Department of Energy (DOE) indicates that residential and commercial buildings are responsible for nearly 39% of total primary energy consumption in the United States. Seventy-five percent of the $400 billion annual electricity consumption is due to commercial buildings.

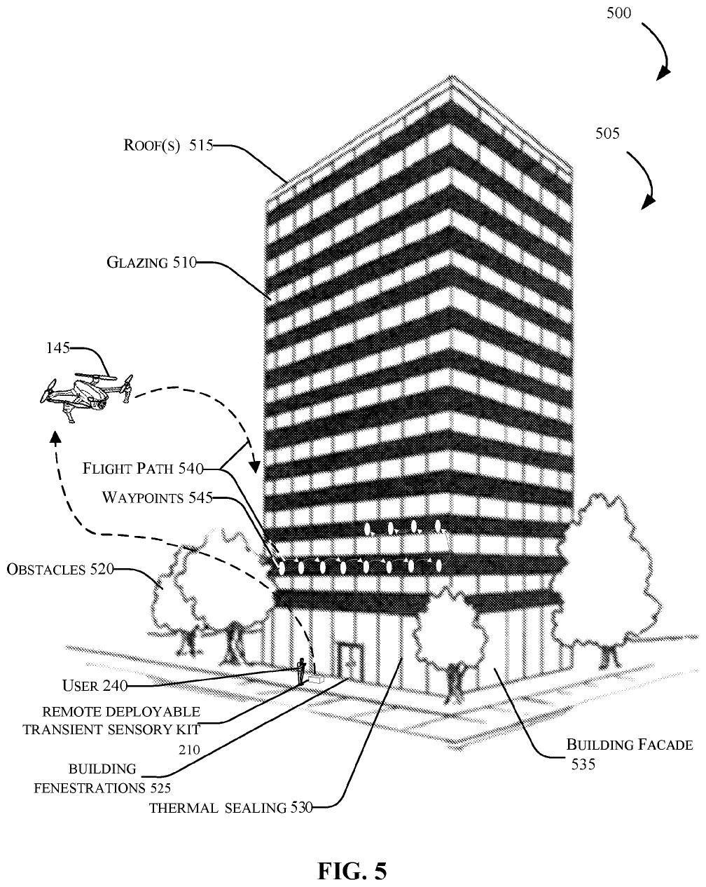

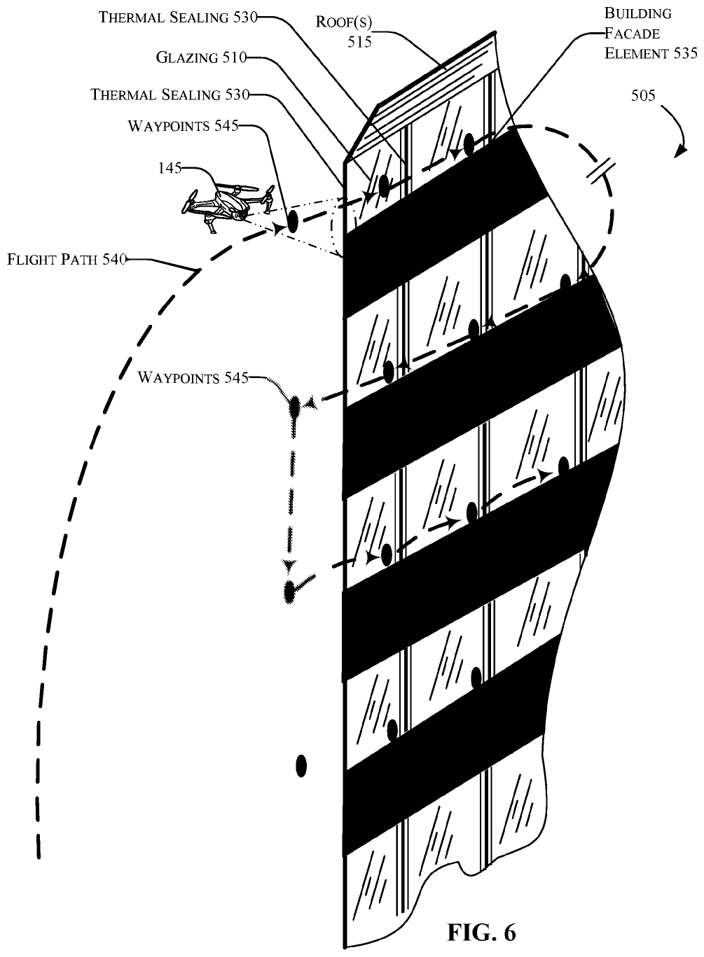

Building envelope is a term that encompasses the walls, doors, windows, roofs, and skylights of any built environment through which thermal energy transfers as the ambient temperature changes throughout the day. FIGS. 5 and 6, discussed in greater detail hereafter, describe aspects of an example building envelope that are analyzed according to embodiments of the present disclosure. By way of an overview, an exchange of energy through the building envelope between the inside conditioned space and the outside ambient space is a function of the temperature and pressure differences between interior and exterior environments. The temperature and pressure differential may be a significant source of a building's operating inefficiencies. Building envelope energy losses are frequently due to poor installation of thermal insulation, aging of the structure and to the infiltration of unconditioned air into the conditioned spaces. Therefore, building energy efficiency can be improved by initially using higher quality elements within the building envelope, properly sealing gaps between building components and resolving existing deficiencies which are key to reducing energy consumption. This “tightening” of the building envelope more effectively keeps the conditioned air inside of the building envelope. Building envelope tightening may reduce thermal and moisture loads experienced by the HVAC systems, thereby reducing the amount of energy needed to maintain the indoor environment, and increase the energy efficiency at which they operate.

Acquiring knowledge about the actual heat transfer paths through the components of the building envelope is a necessary step in assessing the sustainability of a building's structure. However, tightening the building envelope is far from a trivial matter in many cases because a built environment may extend many floors above ground level, and have thousands, tens of thousands, hundreds of thousands and even millions of square feet to analyze and inspect before sources of energy inefficiencies are discovered, analyzed, and remediated.

Energy efficiency is measurable in various ways, but most generally in terms of thermal resistance. Thermal resistance is sometimes described in terms of a variable commonly referenced today as R-value. The R-values of the components that make up a building's envelope is used in estimating the energy efficiency and expected performance of that building, where lower R-value is associated with energy inefficiency, and higher R-value is associated with energy efficiency. Overall, the building envelope is currently responsible for about 25% of the total energy loss in built environments in the United States, but can impact up to 42% of energy loss in residential buildings, and 57% of energy loss in commercial buildings. Therefore, improving the building envelope offers significant opportunity for building energy efficiency. In addition to energy savings, tightening the building envelope will also improve the indoor air quality of occupied spaces resulting in improved comfort of building occupants.

Building energy efficiency improvements are often challenging because building envelope R-values can be consistent (homogeneous) throughout the area of a building envelope component. This is especially true for older buildings. R-values can change over time due to environmental conditions, material deterioration, and building modifications and usage. R-value performance can decline as much as 50% over time. Therefore, there is a need to determine the in-situ R-values of existing building envelope components to quantify actual and projected changes before implementing any building envelope improvement project.

Since some of the components of the building envelope have very large surface areas, data collection for quantification of the heat transfer through a building envelope is time-consuming and costly. As a result, energy management personnel seldom prioritize building envelope improvement projects due to the difficulty in identifying existing insulation and sealing deficiencies and the associated lack of reliable data regarding the energy performance of the building envelope. An accurate, rapid data collection process can assist with overcoming these limitations. Building management can use this data to implement building envelope improvement projects with confidence in the projected savings. In this aspect, the ability to survey and assess all aspects of the building envelope in an efficient and timely manner, with minimal human work hours, is of paramount importance when calibrating large built environment projects, and for maintaining accurate monitoring over time as the building envelope ages and thermal sealing weathers and degrades over time. Stated another way, the building envelope may not be tightened until the building is first analyzed in detail, thermal leaks are identified, and the root causes for those leaks are remedied.

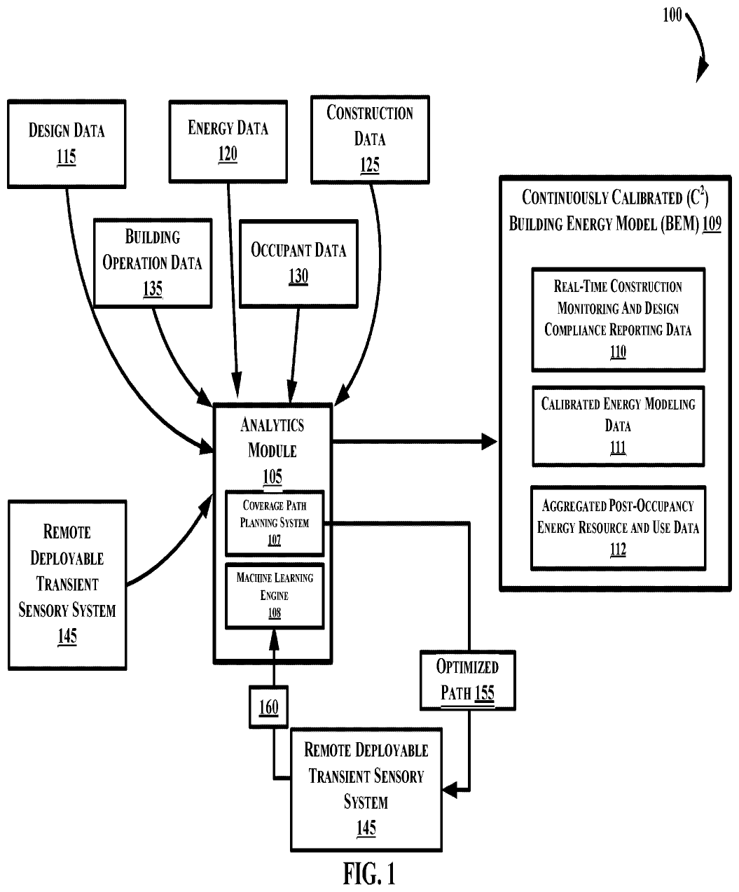

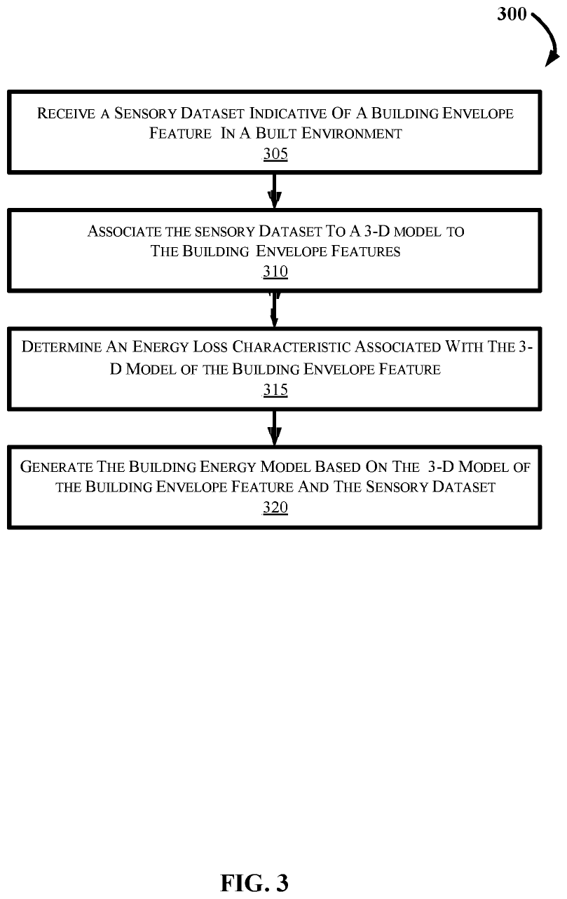

Now considering aspects of the present disclosure in greater detail, Section I considers a system and method for C²BEM associated with a built environment. FIGS. 1-3, among others, provide example embodiments describing systems and methods with which the C² BEM is created. Section II describes a computer-implemented method for generating a flight/terrestrial travel plan for a remote deployable transient sensory system using a coverage path planning system, and using that flight/terrestrial travel plan to generate a sensory dataset used in generating the C² CBEM. FIGS. 3-9 depict aspects of generation of a flight plan using the system of Section I. Section III considers a computer-implemented method for training an artificial intelligence engine used in the system of Sections I and II. Finally, in Section IV, systems and methods for providing a remote deployable transient sensory system kit are considered, where a deployable device and auxiliary equipment may be delivered to a building owner with no aerial system operation experience, and to deploy the system of Sections I and II after receiving the kit.

### Section I—Generation of a Continuously Calibrated Building Energy Model (C² BEM)

By way of a general overview, the energy model calibration system 100 may generate a C² BEM associated with a built environment by receiving from the remote deployable transient sensory system 145 a sensory dataset indicative of a building envelope feature. The remote deployable transient sensory system 145 may be deployed in flight (when configured as an unmanned aerial vehicle (UAV)) or on the ground (when configured as an unmanned ground vehicle (UGV)). When obtaining sensory data, the remote deployable transient sensory system 145 may be disposed proximate to a building envelope (e.g., within 1 meter, 2 meters, 3 meters, 10 meters, etc.). In certain environmental conditions (e.g., open-sky, obstacle-free, low or no wind conditions) it is possible to achieve up to 2 cm GPS accuracy with currently available aerial vehicles (such as, for example, the DJI Matrice 300 RTK®) for a building envelope feature being sensed. Accordingly, the building envelope feature may, in some embodiments, be disposed on an exterior surface of the built environment.

FIG. 1 is a block diagram of an energy model calibration system 100 (hereafter “the energy model calibration system 100”), in accordance with an embodiment of the present disclosure. The energy model calibration system 100 includes an analytics module 105 having a coverage path planning system 107 and a machine learning engine 108. Within the machine learning engine, simulation occurs using building data gained from various sources. This simulation is then coupled with machine learning and optimization techniques to obtain a more accurate and representative model of the built environment. The energy model calibration system 100 may further include one or more remote deployable transient sensory systems 145. In some aspects, the analytics module 105 may receive and digest data from various data sources to optimize a flight or terrestrial travel path (“optimized path 155”) for the remote deployable transient sensory system 145, and generate a continuously calibrated (C²) BEM 109.

The energy model calibration system 100 may utilize a wide variety of input data to optimize the flight and/or terrestrial travel path and generate the C² BEM 109, which may be used as a basis for understanding the energy performance gaps in typical modern construction of the built environment, and for a simulation and data-centric approach for optimization of the energy usage for an existing built environment. In one example embodiment, data sources may include structure design data 115, the sensory energy data 120, construction data 125, occupant data 130, real-time building operations data 135, sensory energy data 120 from preexisting building, and data received from one or more remote deployable transient sensory systems 145, among others. The system may obtain the data from these different sources and analyze it to improve the calibrated energy model's accuracy and identify areas of improvement that can help reduce energy consumption.

The system may obtain the sensory data using the remote deployable transient sensory system 145 for multiple purposes, and may perform the sensory acquisitions during multiple flight/terrestrial missions. For example, a first flight/terrestrial mission may have a goal of sensing building envelope features, generating a sensory dataset of those features, and transmitting the sensory dataset to a mobile device, computer, or server for processing and creation of a three-dimensional (3-D) point cloud model. Accordingly, the energy model calibration system 100 may modify the point cloud model to include the building envelope feature associated with the sensory dataset, such that the 3-D point cloud model is created as an accurate digital representation of the building. In some aspects, generating the 3-D point cloud model may include creation of the model when a prior model is not available. In other aspects, generating the point cloud model may include modification of the existing model to include or improve digital representation of the building envelope feature. According to one or more embodiments, the point cloud may also include the obstacle information which can be utilized to generate a 3-D collision-free inspection path.

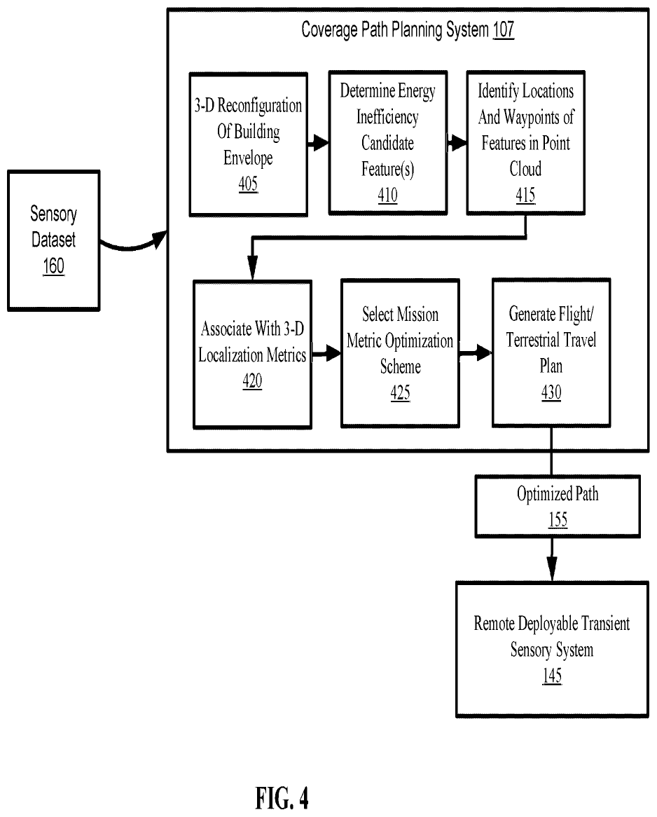

After creation of the 3-D point cloud model, the energy model calibration system 100 may develop a travel path plan (described in greater detail with respect to FIG. 4), and deploy the remote deployable transient sensory system 145 with the task of determining, based on the 3-D point cloud model, an energy loss characteristic associated with a building envelope feature. During the initial flight/terrestrial mission, the remote deployable transient sensory system 145 may obtain 3-D point cloud information using onboard sensors, transmit the dataset to the analytics module 105, and be sent for a second mission to identify energy loss portions. This identification of energy losses can come about from analysis of the data and/or machine learning techniques that are trained to spot certain failures within a built environment. As the system gains more data on the building, and more building data, the automatic diagnosis of buildings will improve. In one or more embodiments, the second mission (flight or terrestrial) may be executed immediately after execution of the first flight path and/or terrestrial travel path, either without returning to the home position, or after returning to the home position (e.g., to recharge or replace vehicle batteries, etc.). For example, the energy model calibration system 100 may analyze the 3-D point cloud model to anticipate and/or predict building envelope features that may be associated with energy loss characteristics. The system may use such a prediction to generate a 3-D flight plan and/or terrestrial travel plan for the remote deployable transient sensory system 145, where the plan includes instructions for navigation and collection of sensory dataset(s) that can identify and confirm energy losses. Accordingly, the energy model calibration system 100 may determine, based on the 3-D point cloud model, an energy loss characteristic associated with the building envelope feature, and generate the C² BEM 109 based on the point cloud model and the sensory dataset.

For example, generating the unmanned aerial system (UAS) flight path and/or the terrestrial travel path plan may include identifying, via an artificial intelligence (AI) engine, a candidate source cause of the energy loss characteristic, and generating a mathematical optimization model solution to control the UAS to a plurality of locations proximate to the plurality of waypoints. The waypoints may be determined by the system according to respective 3-D positions of a built environment feature of interest (e.g., the windows, sealing points, mechanical equipment, etc.). The energy model calibration system 100 may update the UAS flight path and/or terrestrial travel plan with instructions that, when executed, control the UAS and/or UGV to fly/navigate to the plurality of locations proximate to the plurality of waypoints. When positioned at respective locations proximate to the plurality of waypoints, the remote deployable transient sensory system 145 may generate a sensory dataset(s) that can be used to confirm energy loss characteristics. Generation of the sensory dataset(s) may occur during the initial flight/terrestrial mission, subsequent to the initial flight/terrestrial mission before returning to the home position, or after returning to the home position.

In some aspects, the C² BEM 109 may identify a building envelope feature, and may include a mitigation recommendation to reduce energy loss associated with the energy loss characteristic. The mitigation recommendation may include specific recommendations for tightening the building envelope. For example, as explained in further portions of this disclosure, the building envelope feature may include a heating, ventilation and air conditioning (HVAC) component, and the mitigation recommendation may be to investigate observed cold air loss in a supply line that was observed while capturing thermographic imagery on a rooftop. In another example, the mitigation recommendation may be to re-seal identified air gaps observed while executing a flight path and/or terrestrial travel path, where a glazing element (e.g., building window seal) has shown signs of material failure due to degradation of the sealing media. In yet another example, the building envelope feature may include a roof element such as a penetration for mechanical, electrical, and plumbing (MEP) components, where the penetration has observable air gaps, moisture or energy loss. In yet another example, the building envelope may include sections that receive an amount of solar gain above a defined threshold and thus require shading techniques on the windows to decrease the solar gain which in turn decreases energy need and consumption.

The mitigation recommendation may further include one or more remediation steps, such as, for example, adding additional sealant or other materials or devices to remedy the energy inefficiency associated with that building envelope feature. In yet another example, the building envelope feature may be a building facade portion having fasteners that were misapplied during construction, which may be causing energy loss from the built environment interior to the built environment exterior. The mitigation recommendation in this example may include repair of the misapplied fasteners, addition or repair of building wrap products at key energy loss points, reapplication of sealant media, etc. The mitigation recommendation may also include specific technologies that can reduce energy loss such as lighting changes, building envelope material changes, or operational schedule optimization recommendations. Lighting changes may help to reduce the overall energy load that a built environment creates. Building envelope material changes may help reduce the built environment's overall energy needed to meet the built environment's required operating temperatures. Operational schedule recommendations would help to find an optimal schedule for different aspects of the building's needs. An example of this is changing the setpoint temperature by the hour to account for larger energy need in the morning/afternoon.

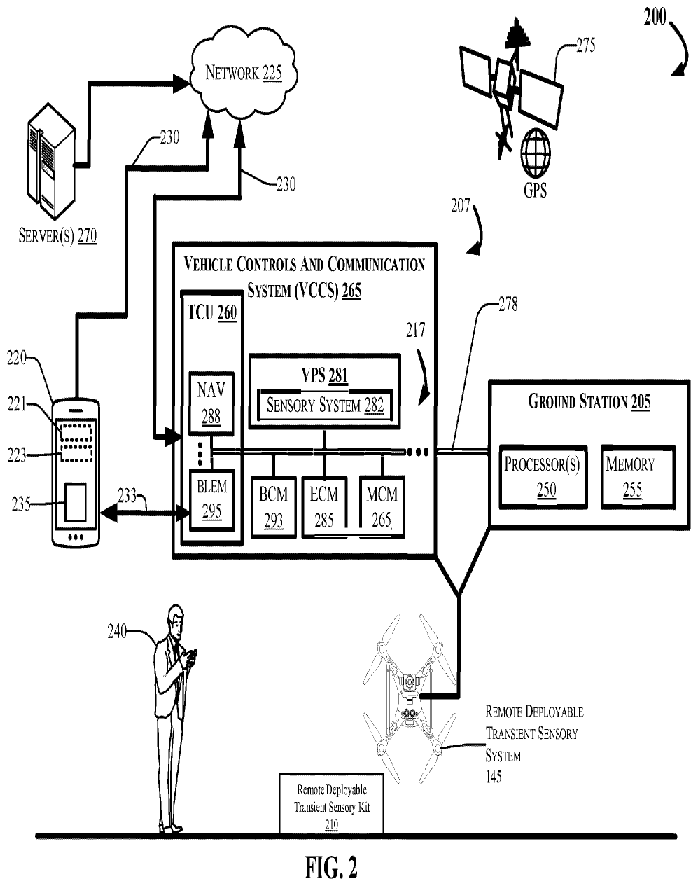

The energy model calibration system 100 may receive input data sources 115-135 through input of legacy datasets associated with the structure design data 115 and the construction data 125. The energy model calibration system 100 can use the input data sources 115-135 to generate the C² BEM 109. In some aspects, the analytics module 105 may receive the input data independent of additional information received using the remote deployable transient sensory system 145 (discussed in greater detail with respect to FIG. 2, among other sections). The granularity and accuracy of the C² BEM 109 may be increased with increased sources, capabilities, and volume of information. Stated another way, the more data the energy model calibration system 100 collects, and the greater the variety of sources for that data, the more comprehensive and reliable the data predictions will be when using the C² BEM 109 to produce those predictions. Thus, as the energy model calibration system 100 continues to gain more information, it will lead to a more accurate C² BEM 109 of the building(s) in question. This gain in information can include but is not limited to new aspects of the building that were not known prior to building completion/occupancy, or data obtained from the use of transient sensors. Once the energy model calibration system 100 gains a volume of data that may support a machine learning training procedure, machine learning techniques can be used for modeling, diagnosis, and recommendations to help improve the building's energy efficiency.

Machine learning techniques can be used to model the data from the transient sensors and analyze the modeled data to then input it within the energy model. For example, the transient data gained from remote deployable transient sensory systems 145 may help to properly define the window-to-wall ratio of a building or more accurately model the shading that encompasses the building envelope. Machine learning techniques can be used in energy loss diagnosis and remediation recommendations through training a machine learning model that takes in data from transient sensors (e.g., a sensory dataset 160) and identifies problems and finds solutions based on the sensory dataset 160. For example, thermal leaks can be identified through data gained from remote deployable transient sensory systems 145 and then solutions, as well as the benefits of the solutions, can be identified.

The energy model calibration system 100 may also actively collect the input data 110-135 using real-time building operation data 135, occupant data 130 that may change over time as the building use changes, and sensory energy data 120 from the preexisting building. Moreover, as explained in greater detail with respect to FIGS. 1-14, the analytics module 105 may utilize the remote deployable transient sensory system 145 to collect building envelope information used to generate a point cloud. The energy model calibration system 100 may then develop the optimized path 155 which the remote deployable transient sensory system 145 may utilize to minimize time needed to identify actual causes of energy inefficiencies in the built environment. Generation of the optimized path is discussed in greater detail with respect to FIG. 4.

Most built environment construction projects, commercial buildings, apartment complexes, hospitals, and the like, may be referenced by their overall size measurement, such as square footage/meters. For example, a particular property manager may manage 10 million square feet of property. The square footage may be distributed among a few buildings, or in many smaller buildings. As the energy model calibration system 100 collects additional energy performance information, the reliability of the overall data improves. According to one embodiment, the energy model calibration system 100 may include anywhere between 10 million to 100 million square feet of data, for example. Any size of built environment may be a functional workspace according to embodiments described herein.

According to another aspect, the energy model calibration system 100 may collect structure design data 115, sensory energy data 120, and/or construction data 125. In a preferred embodiment, the structure design data 115 and sensory energy data 120 may be available for a building in electronic or other forms. In another aspect, although not as detailed and complete as with additional data sources, a relatively smaller volume of input data may be used to create the C² BEM 109, such as utilizing only structure design data 115 and real-time building operation data 135. Although not as complete or detailed as possible, even such a reduced volume and variety of data with respect to a dataset that includes full structure design data 115 which may include a 3-D file of the structure (if such data is available), and/or sensory energy data 120, and/or construction data 125, could still provide a significant improvement in the quality of the C² BEM 109 when processed using the energy model calibration system 100. This improvement comes about from an incorporation of machine learning and optimization techniques that help to improve the accuracy of the model during and after simulation.

One benefit of the energy model calibration system 100, as compared to conventional systems, is that the energy model calibration system 100 may include systems and mechanisms for continuous calibration of an energy modeling dataset 111, which may be part of the output associated with the C² BEM 109. In typical construction, resource sensors or monitors may be installed in a built environment during construction; however, there may not be a baseline control that levels respective sensory values, and/or there may not be control factors that make such real-time sensory information relevant for building the C² BEM 109, and/or for providing aggregated post-occupancy energy resource and use data 112. In some aspects, the sensors, or monitors (not shown in FIG. 1) configured for post-occupancy monitoring need not be selected in advance. Once desired data is selected, the transient sensory systems, as described, can be fitted with the appropriate sensor configurations to generate the desired data. This may help to mitigate sensors aging and becoming technologically obsolete over time. This may also significantly reduce overhead cost for the system since transient sensory systems may be reused and/or reconfigured on a regular basis. The energy model calibration system 100 can include data from original building sensors that were installed during construction, however, fewer sensors may be installed once transient sensory systems as described herein become available to consumers in the building industry.

According to one embodiment, the energy model calibration system 100 collects occupant data 130. In this embodiment, the occupant data, which can include users, property managers or anyone else having contact with the built environment provides not only an understanding of the building operations data, but also allows the energy model calibration system 100 to determine whether there are common underlying causes of occupant issues and if so, to automate a response to those issues. In addition, this occupant data can help the energy model calibration system 100 create a more accurate and representative energy model of the built environment by having an up-to-date status on the occupancy of the building in question at any time. The energy model calibration system 100 can also collect any externally available information, including for example, media and images from commercial drones, or infrared or other images displaying heat losses. Based upon this disclosure, the skilled artisan can recognize additional types of information that may be collected and included within the system based on sensor types.

FIG. 2 depicts an example computing environment 200 that can include the remote deployable transient sensory system 145, which may be the UAS described in portions of the present disclosure. The remote deployable transient sensory system 145 may include a ground station 205, and a Vehicle Controls and Communication System (VCCS) 265 that can include a plurality of electronic control units (ECUs) 217 disposed in communication with the ground station 205. The remote deployable transient sensory system 145 may be disposed in communication with a mobile device 220 during operations such as built environment analysis, built environment surveying to construct a point cloud model, and during construction project monitoring operations when ensuring that a built environment project is within compliance with design specifications and remains on schedule. The mobile device 220, which may be associated with and/or operated by a user 240 and the remote deployable transient sensory system 145, may connect with the remote deployable transient sensory system 145 using wired and/or wireless communication protocols and transceivers. The mobile device 220 may be communicatively coupled with the remote deployable transient sensory system 145 via one or more network(s) 225, which may communicate via one or more wireless connection(s) 230, and/or may connect with the remote deployable transient sensory system 145 directly using near field communication (NFC) protocols, Bluetooth® protocols, Wi-Fi, Ultra-Wide Band (UWB), and other possible data connection and sharing techniques.

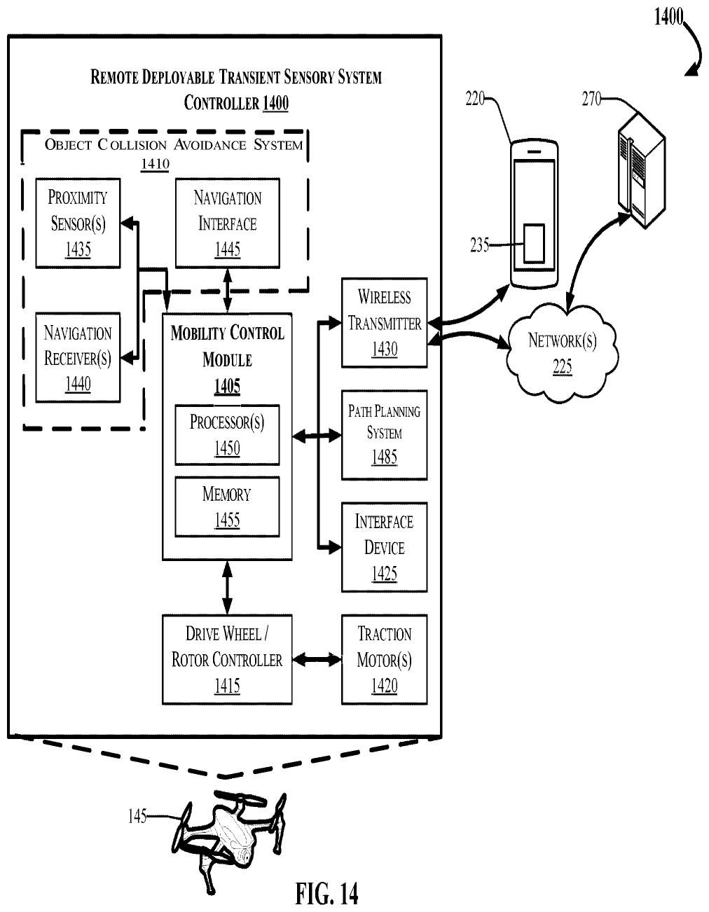

The remote deployable transient sensory system 145 may also receive and/or be in communication with a Global Positioning System (GPS) 275. The GPS 275 may be a satellite system (as depicted in FIG. 2) such as the global navigation satellite system (GNSS), Galileo, or navigation or other similar system. For example, the remote deployable transient sensory system 145 may traverse areas of a building envelope via a flight plan using GPS coordinates received from the GPS 275, and return to a starting position such as a predetermined position proximate to the building (building not shown in FIG. 2). Such a position may also correspond with a mobile home base such as a remote deployable transient sensory kit 210, which is discussed in greater detail with respect to FIG. 14. In other aspects, the GPS 275 may be a terrestrial-based navigation network. In some embodiments, the remote deployable transient sensory system 145 may utilize a combination of GPS and Dead Reckoning responsive to determining that a threshold number of satellites are not recognized.

Although not shown in FIG. 2, the energy model calibration system 100 may further include a beacon device network that may also be used for localization, orientation, and navigation of the remote deployable transient sensory system 145. It is contemplated, therefore, that the GPS 275 may work in conjunction with, and/or independent of such a beacon network.

With continued reference to FIG. 2, the ground station 205 may be or include an electronic vehicle controller, having one or more processor(s) 250 and memory 255. The remote deployable transient sensory system 145 (described more fully with respect to FIG. 14) may communicate with external devices such as the mobile device 220, the network(s) 225, and/or beacon networks (not shown in FIG. 2) via a wireless transmitter/transceiver (e.g., a wireless transmitter 1430 as shown in FIG. 14).

The ground station 205 may, in some example embodiments, be disposed in communication with the mobile device 220, and one or more server(s) 270. The server(s) 270 may be part of a cloud-based computing infrastructure, and may be associated with and/or include a Telematics Service Delivery Network (SDN) that provides digital data services to the remote deployable transient sensory system 145 and other vehicles (not shown in FIG. 2) that may be part of a drone fleet (not shown in FIG. 2).

Although illustrated as a four-prop aerial vehicle, the remote deployable transient sensory system 145 may take the form of another autonomous or semi-autonomous drone vehicle for example, a land-based or water-based vehicle, and may be configured and/or programmed to include various types of automotive drive systems. When configured as an aerial vehicle, the configuration may be as shown or take a different form, having fewer or additional props, a fixed wing, and may include aspects not depicted in the figures. The remote deployable transient sensory system 145 shown is provided as an example embodiment and is not intended to be limiting for possible configurations.

The mobile device 220 can include a memory 223 for storing program instructions associated with an application 235 that, when executed by a mobile device processor 221, performs aspects of the disclosed embodiments. The application (or “app”) 235 may be part of the energy model calibration system 100, or may provide information to the energy model calibration system 100 and/or receive information from the energy model calibration system 100. For example, the app 235 may include an interface for viewing thermographic imagery, red, green, blue (RGB) camera imagery, LiDAR, RADAR, SONAR, RGB identification of thermal leakage, identification, and images of mechanical, electrical and plumbing (MEP) systems and components, etc. This identification may be performed through analysis of the data gained from transient sensors and machine learning techniques. This process can potentially consist of acquiring data from transient sensors, then labeling the data based on certain features that the modeler deems important. The data is then split into train and test data so that machine learning techniques can be applied. The training data will help create a way to identify different aspects in question from the data. The test data is then used to assess accuracy. In other aspects, the app 235 may provide some control mechanisms and features for providing limited instruction sets that control the remote deployable transient sensory system 145 while in flight. For example, the app 235 may provide a button or other control that causes instructions to be sent from the mobile device 220 to the remote deployable transient sensory system 145 that cause the remote deployable transient sensory system 145 to execute a return to home protocol, where the remote deployable transient sensory system 145 notes the position at which it currently operates, saves current position to a computer-readable memory, and returns to a home base position responsive to actuation of such a control.

In another embodiment, the app 235 provides current views of a construction environment when the energy model calibration system 100 is utilized for construction observation and compliance monitoring. For example, the app 235 may include user-selectable features (not shown in FIG. 2) that provide a selectable control that causes an instruction set to be sent from the mobile device 220 to the remote deployable transient sensory system 145, causing the remote deployable transient sensory system 145 to perform actions such as obtaining close-up views and imagery of a selectable feature, perform testing on one or more construction features such as fastener placement, MEP identification and observation, logistics identification where deliveries and logistics associated with equipment needed on a job site are observed, identified, measured, etc., and/or other task-specific instructions.

In some aspects, the mobile device 220 may communicate with the remote deployable transient sensory system 145 through the one or more wireless connection(s) 230, which may be encrypted and established between the mobile device 220 and a Telematics Control Unit (TCU) 260. The mobile device 220 may communicate with the TCU 260 using a wireless transmitter (not shown in FIG. 2) associated with the TCU 260 on the remote deployable transient sensory system 145. The transmitter may communicate with the mobile device 220 using a wireless communication network such as, for example, the one or more network(s) 225. The wireless connection(s) 230 are depicted in FIG. 2 as communicating via the one or more network(s) 225, and via one or more wireless connection(s) 233 that can be direct connection(s) between the remote deployable transient sensory system 145 and the mobile device 220. The wireless connection(s) 233 may include various low-energy protocols including, for example, Bluetooth®, Bluetooth® Low-Energy (BLE®), UWB, Near Field Communication (NFC), or other protocols.

The network(s) 225 illustrate an example communication infrastructure in which the connected devices discussed in various embodiments of this disclosure may communicate. The network(s) 225 may be and/or include the Internet, a private network, public network or other configuration that operates using any one or more known communication protocols such as, for example, transmission control protocol/Internet protocol (TCP/IP), Bluetooth®, BLE®, Wi-Fi based on the Institute of Electrical and Electronics Engineers (IEEE) standard 802.11, UWB, and cellular technologies such as Time Division Multiple Access (TDMA), Code Division Multiple Access (CDMA), High Speed Packet Downlink Access (HSPDA), Long-Term Evolution (LTE), Global System for Mobile Communications (GSM), and Fifth Generation (5G), to name a few examples.

The ground station 205 may be installed in an engine compartment of the remote deployable transient sensory system 145 (or elsewhere in the remote deployable transient sensory system 145) and operate as a functional part of the energy model calibration system 100, in accordance with the disclosure. The ground station 205 may include one or more processor(s) 250 and a computer-readable memory 255.

The one or more processor(s) 250 may be disposed in communication with one or more memory devices disposed in communication with the respective computing systems (e.g., the memory 255 and/or one or more external databases not shown in FIG. 2). The processor(s) 250 may utilize the memory 255 to store programs in code and/or to store data for performing aspects in accordance with the disclosure. The memory 255 may be a non-transitory computer-readable memory storing a calibrated energy modeling program code. The memory 255 can include any one or a combination of volatile memory elements (e.g., dynamic random-access memory (DRAM), synchronous dynamic random-access memory (SDRAM), etc.) and can include any one or more nonvolatile memory elements (e.g., erasable programmable read-only memory (EPROM), flash memory, electronically erasable programmable read-only memory (EEPROM), programmable read-only memory (PROM), etc.

The VCCS 265 may share a power bus 278 with the ground station 205, and may be configured and/or programmed to coordinate the data between UAS computer systems, connected servers (e.g., the server(s) 270), and other vehicles (not shown in FIG. 2) operating as part of a vehicle fleet. The VCCS 265 can include or communicate with any combination of the ECUs 217, such as, for example, a Body Control Module (BCM) 293, an Engine Control Module (ECM) 285, the TCU 260, a Navigation (NAV) receiver 288, a BLE® Module (BLEM) 295, etc. The VCCS 265 may further include and/or communicate with a Vehicle Perception System (VPS) 281, having connectivity with and/or control of one or more vehicle sensory system(s) 282. In some aspects, the VCCS 265 may control operational aspects of the remote deployable transient sensory system 145, and implement one or more instruction sets received from the application 235 operating on the mobile device 220, from one or more instruction sets stored in computer memory 255 of the ground station 205, including instructions operational as part of the calibrated energy modeling system 207.

The TCU 260 can be configured and/or programmed to provide vehicle connectivity to wireless computing systems onboard and offboard the remote deployable transient sensory system 145, and may include a Navigation (NAV) receiver 288 for receiving and processing a GPS signal from the GPS 275, a BLE® Module (BLEM) 295, a Wi-Fi transceiver, a UWB transceiver, and/or other wireless transceivers (not shown in FIG. 2) that may be configurable for wireless communication between the remote deployable transient sensory system 145 and other systems, computers, and modules. The TCU 260 may be disposed in communication with the ECUs 217 by way of a bus (not shown in FIG. 2). In some aspects, the TCU 260 may retrieve data and send data as a node in a CAN bus.

The BLEM 295 may establish wireless communication using Bluetooth® and BLE® communication protocols by broadcasting and/or listening for broadcasts of small advertising packets, and establishing connections with responsive devices that are configured according to embodiments described herein. This module may be useful when the mobile device 220 is within the line of sight with respect to the remote deployable transient sensory system 145, and proximate to the remote deployable transient sensory system 145 such that low energy communication is a practical choice. For example, the BLEM 295 may include Generic Attribute Profile (GATT) device connectivity for client devices that respond to or initiate GATT commands and requests, and connect directly with the mobile device 220.

The bus (not shown in FIG. 2) may be configured as a Controller Area Network (CAN) bus organized with a multi-master serial bus standard for connecting two or more of the ECUs 217 as nodes using a message-based protocol that can be configured and/or programmed to allow the ECUs 217 to communicate with each other. The bus (not shown in FIG. 2) may be or include a high-speed CAN (which may have bit speeds up to 1 Mb/s on CAN, 5 Mb/s on CAN Flexible Data Rate (CAN FD)), and can include a low-speed or fault tolerant CAN (up to 125 Kbps), which may, in some configurations, use a linear bus configuration. In some aspects, the ECUs 217 may communicate with a host computer (e.g., the ground station 205, the energy model calibration system 100, and/or the server(s) 270, etc.), and may also communicate with one another without the necessity of a host computer. The bus may connect the ECUs 217 with the ground station 205 such that the ground station 205 may retrieve information from, send information to, and otherwise interact with the ECUs 217 to perform steps described according to embodiments of the present disclosure. The bus may connect CAN bus nodes (e.g., the ECUs 217) to each other through a two-wire bus, which may be a twisted pair having a nominal characteristic impedance. The bus may also be accomplished using other communication protocol solutions, such as Media Oriented Systems Transport (MOST) or Ethernet. In other aspects, the bus may be a wireless intra-vehicle bus.

The VCCS 265 may control various loads directly via the bus communication or implement such control in conjunction with the BCM 293. The ECUs 217 described with respect to the VCCS 265 are provided for example purposes only, and are not intended to be limiting or exclusive. Control and/or communication with other control modules not shown in FIG. 2 is possible, and such control is contemplated.

In an example embodiment, the ECUs 217 may control aspects of vehicle operation and communication using inputs from human operators (when the remote deployable transient sensory system 145 is semi-autonomous), inputs from an autonomous vehicle controller, the energy model calibration system 100, and/or via wireless signal inputs received via the wireless connection(s) 233 from other connected devices such as the mobile device 220, among others. The ECUs 217, when configured as nodes in the bus, may each include a central processing unit (CPU), a CAN controller, and/or a transceiver (not shown in FIG. 2). These aspects are discussed in greater detail. For example, although the mobile device 220 is depicted in FIG. 2 as connecting to the remote deployable transient sensory system 145 via the BLEM 295, it is possible and contemplated that the wireless connection 233 may also or alternatively be established between the mobile device 220 and one or more of the ECUs 217 via the respective transceiver(s) associated with the module(s).

The BCM 293 generally includes integration of sensors, vehicle performance indicators, and variable reactors associated with vehicle systems, and may include processor-based power distribution circuitry that can control functions associated with the vehicle body such as lights, security, and remote deployable transient sensory system access control. The BCM 293 may also operate as a gateway for bus and network interfaces to interact with remote ECUs (not shown in FIG. 2).

The BCM 293 may coordinate any one or more functions from a wide range of vehicle functionality, including energy management systems that control battery usage, alarms signaling battery depletion, obstructions, tampering, theft, or other conceivable situations, vehicle immobilizers, operator access authorization systems, drone tracking systems, etc. The BCM 293 may be configured for vehicle energy management, and exterior lighting control to illuminate building envelope portions. In other aspects, the BCM 293 may control auxiliary equipment functionality, and/or be responsible for integration of such functionality.

The ground station 205 may obtain the sensor information from a sensory system 282, which may include sensors disposed on a vehicle exterior and in devices connectable with the remote deployable transient sensory system 145 such as the mobile device 220. The sensory system 282 may connect with and/or include one or more inertial measurement units (IMUs) (not shown in FIG. 2), camera sensor(s) (not shown), and/or other sensor(s), and obtain data usable for characterization of the sensor information for identification of features. Such information may be stored in a secure data vault (not shown in FIG. 2) onboard the remote deployable transient sensory system 145, on the server(s) 270, and/or in other location(s) not shown in FIG. 2, which may be accessible via the network 225 to obtain environmental data for providing the remote deployable transient sensory system assistances features. The 205 may obtain, from the VPS 281, sensory data that can include sensor response signal(s) via a sensor input/output (I/O) module (not shown in FIG. 2). The ground station 205 may characterize the sensory data, and/or may transmit the sensory data to the mobile device 220 and/or the server(s) 270, and generate a 3-D point cloud model used in creation of the C² BEM 109 using the point cloud model and the sensor dataset.

More particularly, the VPS 281 may provide the sensory data obtained from the sensory system 282 responsive to computer-readable instructions included in the optimized path received from the coverage path planning system 107 (discussed previously in FIG. 1). The coverage path planning system 107 may analyze the 3-D point cloud model (not shown in FIG. 2) to generate a 3-dimensional (3-D) flight path and/or terrestrial travel path, and analyze the travel path based on the characteristic of interest representing a building envelope feature associated with a possible or predicted source of building energy inefficiency. The coverage path planning system 107 may further provide computer-readable instructions that indicate which of the respective sensor system(s) in the VPS 281 are to obtain the sensory data used as input to the analytics module 105 (as shown in FIG. 1). These features will be described more fully with respect to FIGS. 3 and 4.

The VPS 281 may include, for example, one or more camera sensor(s), thermal cameras, LiDAR, RADAR, SONAR, optical cameras, and/or a hybrid camera having optical, thermal, or other sensing capabilities. Thermal cameras may provide thermal information of objects within a frame of view of the camera(s), including, for example, a heat map figure of an energy loss characteristic associated with the building envelope, as that object appears in the camera frame. An optical camera may provide a color and/or black-and-white image data of the target(s) within the camera frame. The camera sensor(s) may further include static imaging, or provide a series of sampled data (e.g., a camera feed) to the vehicle controls and communication system. In addition, the data gained from thermal and optical cameras can be used to improve the accuracy of the energy model of the building. The sensory system 282 may further include one or more IMU(s) that can include, for example, a gyroscope, an accelerometer, a magnetometer, or other inertial measurement device.

The computing system architecture of the ground station 205, VCCS 265, and/or the energy model calibration system 100 may omit certain computing modules. It should be readily understood that the computing environment depicted in FIG. 2 is an example of a possible implementation according to the present disclosure, and thus, it should not be considered limiting or exclusive.

### Section II—Generating a Flight Plan for a Remote Deployable Transient Sensory System

An initial step for generating the C² BEM 109 can include inquiring from a building owner or manager whether the structure design data 115 is available for import into energy model calibration system 100. In some aspects, the C² BEM 109 may be generated using, at least in part, a 3-D model of the building envelope (e.g., as part of the structure design data 115 depicted in FIG. 1) where a first sensory dataset that includes external features of the structure exists already and is available. The design data may include one or more Revit files, ArchiCAD files, STL files, IGES files or any other type of translatable 3-D design file.

In other aspects, the design data may not be available for incorporation into the C² BEM 109. This is most often the case for older structures built more than several years ago, where building ownership may have changed, or original computer models of the building design are not currently accessible. In some aspects, a 3-dimensional data file of the building envelope may not be available for recently-built structures for various reasons. In such cases, the structure design data 115 (as shown in FIG. 1) may be generated without an existing 3-D model of the building envelope using techniques and commercially available building mapping systems known in the art. This can include deploying the remote deployable transient sensory system 145 (or another drone sensory system configured for scanning external features of a building envelope) and producing a point cloud or other 3-D model of the building envelope. This may include performing a first flight/terrestrial mission that traverses the built environment to generate a dataset using the onboard sensory devices of the remote deployable transient sensory system to create a 3-D model of the building envelope representing the “skin” or exterior of the building or other structure in the built environment. The 3-D model may capture dimensions, topical features, and relative locations for the features of the building envelope that may be observable from the exterior of the building, without design or dimensional data of internal features. The 3-D model may further include localization data provided with respect to GPS or other world-localizing coordinates.

More particularly, and as explained in Section I, the remote deployable transient sensory system 145 may be deployable for various types of flight/terrestrial missions, including generating sensory data usable by the energy model calibration system 100 for generation of a 3-D model of the building envelope that represents a digital version of the actual built environment, and using the created 3-D model (or an existing 3-D model if one is available) to identify and characterize building envelope features associated with energy inefficiencies. In the latter step, the sensory dataset may be used to produce the C² BEM 109. An example of producing a building energy model (BEM) using such a sensory dataset is described in hereafter with respect to FIG. 3.

There are multiple scenarios for deploying the remote deployable transient sensory system 145, including capturing structural imagery and sensory information that may be used to construct the 3-D point cloud model in the case that a pre-existing 3-D model of the building envelope does not exist, and also capturing information that's usable to identify and characterize building envelope features that may be correlated with an existing 3-D model or point cloud. For example, in the case that a 3-D model of the building envelope is not currently available, the system may be used to create one. The remote deployable transient sensory system 145 may traverse exterior surfaces of the built environment (e.g., a building such as the example structure shown in FIG. 6 or another type of built environment) to capture sensory data associated with building envelope elements. The remote deployable transient sensory system 145 may traverse the built environment by following a flight plan (the creation of which being described in later sections), generate a sensory dataset using an onboard sensory system, and transmitting the dataset to the analytics module 105 responsive to having traversed the entire building envelope such that the 3-D point cloud model (or alternatively, a non-point cloud 3-D model) may be created or augmented in a relatively accurate way. A relatively accurate way may be defined as a digital 3-D model of a structure in a built environment that incudes dimensional data associated with building envelope features. The building envelope features observed by the remote deployable transient sensory system 145 may be dimensionally accurate within fractions of an inch using known systems and technologies for mapping building envelope features using drone and sensory technology.

FIG. 3 is a flow diagram illustrating an example method 300 for generating the C² BEM 109 using the energy model calibration system 100 of FIGS. 1 and 2, according to an embodiment of the present disclosure. FIG. 3 considers the general steps for generating the C² BEM 109 using a sensory dataset 160. It should be understood that the method 300 includes a preliminary step of either generating a 3-D model of a structure in a built environment, or accessing an existing 3-D model. Using the created or accessed 3-D model of the building envelope the remote deployable transient sensory system 145 may perform steps to generate a flight/terrestrial travel path plan and executing the plan to generate a sensory dataset having observed energy loss and mechanical equipment functionality data. In other aspects, the sensory dataset may include continuously calibrated energy use data received from installed sensory systems disposed in and on the built environment.

A series of general steps are depicted in FIG. 3. At step 305, the method 300 may include receiving a sensory dataset indicative of a building envelope feature in a built environment. For example, the system may receive, from the remote deployable transient sensory system, a sensory dataset after one or more flight or terrestrial missions have been completed where sensory data associated with energy transmission through the building envelope were sensed and a sensory dataset generated. The sensory dataset may include data sensed from the built environment that may indicate energy inefficiencies, and indicate where and what feature(s) may be responsible for the energy inefficiencies. The sensory data may also include mechanical equipment functionality data, among other data described herein, that can inform and increase the accuracy of the C² BEM 109, and be used to mitigate the energy loss characteristics identified by the C² BEM 109. The sensory dataset can include, therefore, observed sensory readings and other data that identify an energy inefficiency feature.

An energy inefficiency feature may be a digital representation and/or quantification of one or more building envelope features such as, for example, those discussed above in Section I. In one or more embodiments, the remote deployable transient sensory system 145 may traverse the built environment in one or more flight/terrestrial missions to generate the sensory dataset that may be used by the analytics module 105 for generation of the C² BEM 109. The sensory dataset may be the product of a first “fact finding” flight/terrestrial mission that maps the building envelope by creating a 3-D representation of the building (e.g., a point cloud model). Accordingly, the system may identify building envelope features and their relative locations. Another type of flight/terrestrial mission includes using the sensory system(s) to measure energy loss and inefficiencies of the building and saving the quantitative measurement data in a sensory dataset. Creation of the sensory dataset 160 are considered in greater detail with respect to FIGS. 5-8.

As introduced above, the flight/terrestrial mission(s) may be used to generate the sensory dataset and can include sensory data associated with a plurality of building envelope features. Building envelope features may be any one or more features that can include, for example, building glazing units or other window elements, a building penetration element, a roofing element, a thermal sealing element, a mechanical equipment element, a building facade element, a structural element, or other similar features. Although not exhaustive, it should be appreciated that building envelope features that may affect energy efficiency can include any number of features not expressly listed herein. Accordingly, and as a matter of practicality, not all possible building envelope features are discussed. Other types of elements may be included, and thus, the list of building envelope features described herein should not be considered limiting.

Responsive to receiving the sensory dataset indicative of a building envelope feature in a built environment (step 305), at step 310 the analytics module 105 may associate the sensory dataset to a 3-D model of the building envelope features. More specifically, the analytics module 105 may characterize one or more data structures associated with the sensed exterior surfaces of the built environment, identify from the 3-D model, a localization of the feature observed to be inefficient. Although discussed in greater detail hereafter, this can include, for example, characterizing data in the sensory dataset associated with energy leakage or loss in the glazing of a building. Many more examples are described hereafter.

At step 315, the energy model calibration system 100 may identify one or more of a plurality of virtual energy efficiency features associated with virtual energy efficiency feature locations of the built environment at step 315. This step may further include creating and/or updating a data structure (e.g., a spreadsheet, database, etc.) to include a map or association of a respective envelope feature with sensory data indicative of an energy inefficiency characteristic. This can include identifying, via the machine learning engine 108 (shown in FIG. 1), (e.g., an artificial intelligence (AI) engine), a candidate source cause of an energy inefficiency characteristic such as, for example, a degraded sealant joint, a weathered building penetration, a malfunctioning mechanical equipment component, etc.

Stated another way, the energy model calibration system 100 may identify where respective sources of energy inefficiencies are located on the building based on the sensory dataset. For example, if the feature is a window of a particular shape or construction type, determine where instances of that window are located on the actual building, and create a digital record of those specifically identified locations, where the digital record is associated with a building location, and more particularly, a specific real-life feature associated with the digital version of that feature in the 3-D model. To perform this step, the energy model calibration system 100 may localize a location for a first feature of the plurality of building envelope features (e.g., a physical localization of a glazing element), localize a location for a second feature of the plurality of building envelope features (e.g., another glazing element), etc., such that sensory data from the sensory dataset is correlated with some or all instances of the digital representation of the building envelope feature. In another example, building envelope features can include building fenestrations associated with the building envelope, among many other possible features. The relative locations, dimensions, and features of those windows may be associated with sensory information in the first sensory dataset. The sensory dataset may include heat loss observations sensed at some or all of the windows, fenestrations, etc., and update the data structure having the associations between the sensory dataset and the 3-D model of the building with sensory data that characterizes an amount of heat or other energy loss/inefficiency.

At step 320, the energy model calibration system 100 may generate the building energy model based on the 3-D model of the building envelope feature and the sensory dataset. More particularly, this step may include generating the C² BEM 109 using the associations that link real-world locations of observed energy inefficiency to representations of those same features in the 3-D model of the building envelope features, including the sensed data with measurement and quantification of actual observed energy loss.

### Generating a 3-D Trajectory Path Optimization

After explaining the over-arching method for generating the C² BEM 109, greater detail will next be given for how the sensory dataset is generated using the remote deployable transient sensory system. To execute the flight/terrestrial mission(s) on which the sensory dataset is generated, the system may create a flight or terrestrial travel plan.

FIG. 4 is a functional schematic of a coverage path planning system, according to embodiments of the present disclosure. According to embodiments of the present disclosure, the coverage path planning system 107 may perform some aspects of generating the 3-D trajectory flight path and/or terrestrial travel path optimization used in generating the sensory dataset described above with respect to FIG. 3.

The flight/terrestrial travel plan may include executable instructions for identifying and sensing building envelope features in an efficient manner that conserves battery resources, time, and overall cost. The system may gain these efficiencies for generating the sensory dataset by reducing or increasing a flight metric during a flight mission while traversing airspace from feature location to feature location. In one aspect, the flight metric may be a flight fuel usage minimization scheme, where the goal of that metric is to reduce the flight fuel usage using techniques known in the art. In another aspect, the flight metric may be a flight time minimization scheme, where the total flight time is minimized using one or more techniques or algorithms such that the UAS flight path and/or terrestrial travel path minimizes a total flight time required to fly proximate to the plurality of locations.

In another example, the metric may be a flight distance minimization scheme. In yet another example, the scheme may include a flight trajectory change minimization scheme, where total turns made by the remote deployable transient sensory system 145 are minimized as a goal of the scheme such that the UAS flight path and/or terrestrial travel path minimizes a count of trajectory changes. In yet another example, the scheme may include a flight trajectory based on the cardinal direction of each facade elevation of the built environment to reduce vehicle flyover of pedestrians. According to another example embodiment, the scheme may include a flight and/or vehicle count minimization scheme, where a count of total missions/flights is minimized, and/or a number of vehicles required to complete a mission is minimized. Other schemes are possible and known in the art of drone path planning.

The remote deployable transient sensory system 145 may execute the flight plan using an onboard processing system to perform the flight and/or terrestrial navigation steps for collecting the data. For example, the remote deployable transient sensory system 145 may receive data from the coverage path planning system 107, UAS flight path and/or a terrestrial travel path comprising a plurality of waypoints associated with the building envelope. The waypoints may be associated with the building envelope feature determined to be a possible or probable source of the energy inefficiency. For example, the waypoints may be a series of points/positions proximate to each of the building windows if the building envelope feature of interest is determined to be the glazing features of the structure. In another example, the waypoints may be a series of points/positions near building fenestrations if the fenestrations are the feature of interest (e.g., determined or suspected causes of energy inefficiency).

With reference to FIG. 4, the coverage path planning system 107 is shown taking in a sensory dataset 160, and outputting the optimized path 155, which may be transmitted to the remote deployable transient sensory system 145. The coverage path planning system 107 may receive the sensory dataset that may result from an initial flight/terrestrial mission using the remote deployable transient sensory system 145, and use the sensory dataset 160 to produce a 3-D reconfiguration of the building envelope 505 as shown in FIG. 5 (in the case that an existing 3-D model was not previously available), and/or update a data structure such as a database or spreadsheet with associations between the sensory dataset and features corresponding to real-world locations and readings recorded in the sensory dataset.

At step 405, the system may generate a 3-D model of the building envelope by receiving data from a flight from which a 3-D flight plan is generated. In one embodiment there may not be an initial 3-D model of the building envelope. In this case, 3-D reconfiguration of the building envelope may include generating a 3-D point cloud model usable for associating features of the built environment with features sensed by the remote deployable transient sensory system 145. In another aspect where there may exist a prior 3-D point cloud model, step 405 may include improvement of the point cloud model with new and/or improved data that characterizes the features of the built environment in the 3-D point cloud.

The functional block 410 describes the determination of an energy inefficiency candidate feature(s). This step may include, for example, using the machine learning engine 108, to determine one or more building envelope features that may be associated with energy inefficiencies.

The machine learning engine 108 may include one or more supervised algorithms that can include linear regression models, logistic regression modules, support vector machine (SVM) models, random forest models, decision trees, and/or use aspects of Bayes' theorem analysis. Reinforcement algorithms may also be used for making determinations described herein. The machine learning engine 108 may be utilized for, in one aspect, understanding energy inefficiency characteristics such as, for example, a degraded sealant joint, an inefficient built environment fenestration, or a malfunctioning mechanical equipment component. For example, the machine learning engine 108 may observe a characteristic such as a sealant joint, and compare learned aspects associated with energy inefficiencies to identify and characterize the built environment features associated with such inefficiencies. In one example embodiment, the machine learning engine 108 may utilize the sensory dataset to evaluate whether a particular sealant joint has a high likelihood of being associated with energy inefficiency. Example characteristics may be blistering, cracking, voids in the sealant joint, discoloration or deterioration, etc. The machine learning engine 108 may observe one or more such features, and use the observation to form a probability of energy loss associated with a particular portion of that building feature.

With respect to supervised machine learning algorithms, the machine learning engine 108 may obtain the datasets associated with the input data sources 115-135 via the remote deployable transient sensory system 145, and apply one or more labeled data algorithms based on known input parameters. For example, the sensory energy data 120 from a preexisting building may include labeled data in the datasets having input parameters that can include average temperatures, energy consumed/expended, square footage information, etc. Other known input parameters may include aspects of building features associated with known energy loss. As explained above, in an example embodiment, degraded sealant media may be associated with energy loss in a building, where input data may suggest amounts of probable energy loss (e.g., a wider gap in the sealant may be known to associate with higher amounts of energy loss). The machine learning engine 108 may associate the input data with an output that correlates the observed characteristics with a quantifiable energy loss (that is, a prediction of quantified energy loss) based on the observed characteristics and the datasets associated with the input data sources 115-135.

In other aspects, the machine learning engine 108 may employ k-nearest neighbors (KNN) classification machine learning algorithms, or other type(s) of supervised and/or unsupervised machine learning algorithms, to determine and classify built environment types when such built environment types are not known. For example, KNN algorithms are sometimes used to classify a set of data points into specific groups or classes based on similarities between data points. In one aspect, the machine learning engine 108 may determine a 3-D flight plan using the first dataset received from the remote deployable transient sensory system 145 by identifying built environment characteristics from the sensory dataset using KNN classification machine learning. In one aspect, the dataset may provide digital representation data showing that the built environment shape is rectangular, approximately 200 feet tall, and includes approximately 500 rectangular surface features that are most likely windows based on their placement with respect to one another, spacing on the structure surface, and reflectivity when sensed with LiDAR, RADAR, SONAR, RGB, IR or other sensors. The machine learning engine 108 may classify a set of data points into specific groups or classes based on similarities between data points observed from a similar commercial building confirmed to be a commercial structure. The machine learning engine 108 may process the sensory dataset using the KNN algorithms to determine that the Euclidean difference between height, position, location, shape, or other features of the built environment are within a marginal threshold of similarity as compared to the known dataset.

The step 415 describes identifying locations and waypoints for those features in the point cloud (not shown in FIG. 4), and associating waypoints with the 3-D localization metrics at block 420. This may include application of an algorithm for 3-D UAS trajectory optimization for the remote deployable transient sensory system 145. The algorithm may include three general steps: terrain modeling, the selection of scanning waypoints, and trajectory optimization. The terrain modeling process can include obtaining a functional model (not shown in FIG. 4) using a Gaussian or other process from terrain information obtained and stored as part of the 3-D model of the building envelope features as described with respect to FIG. 3. In step 415, the coverage path planning system 107, and more particularly, the analytics module 105, may define scanning waypoints based on the terrain model information, sensor specifications quantified in the first sensory dataset, and the predetermined variable associated with desired image resolution. This may take place responsive to completion of two flights/terrestrial missions, which as explained above may be sequential to one another with or without returning to the home position. During a first mission, the system may collect data to augment or build a 3-D model of the building envelope. The second flight can include generating a 3-D collection avoidance route. The machine learning engine 108 may convert the point cloud from the first mission into a 3-D voxel representation, which may simplify a complex point cloud model. This may also improve 3-D collision for the avoidance path.

For the selection of the waypoints, two different approaches are contemplated, which may depend on the direction of the viewing angle of the building envelope feature at hand from the perspective of the remote deployable transient sensory system 145 while executing a mission: a normal offset method and a vertical offset method. In the trajectory optimization, the flight path and/or terrestrial travel path planning algorithm may solve a distance-constraint vehicle routing problem to identify the optimum scanning route based on the waypoints and UAS constraints. According to another example embodiment, the path planning algorithm may solve an energy-constraint vehicle routing problem. Other optimization schemes are possible, and those discussed are provided as examples only.

As shown in block 425, the coverage path planning system 107 may select a mission metric optimization scheme which may include optimizing one or more flight and/or terrestrial navigation metrics, using the generated flight/terrestrial travel plan as shown in block 430. In the last decade, UGVs and UASs such as the remote deployable transient sensory system 145 have become more capable platforms for autonomous built environment surveying because of technological advances in vehicle power systems, such as new battery technologies, advances in material sciences that have resulted in reduced-weight aircraft structures, increased capability sensor systems for observing building envelope features, and autopilot algorithms that can assist the remote deployable transient sensory system 145 to navigate unplanned features in the terrain as it completes its flight/terrestrial mission. The paper “Three-Dimensional UAS Trajectory Optimization for Remote Sensing in an Irregular Terrain Environment (Choi et al.), which is incorporated herein by reference, discusses techniques for navigating unplanned features. By way of a technological overview, a brief discussion of several techniques is introduced as possible approaches to generating the flight/terrestrial travel plan.

For a 3-D mapping mission, defining a flight coverage path has been challenging in prior attempts in the art because of limited battery life that constrains flight endurance time. The typical endurance range of a Commercial Off-The Shelf (COTS) quadcopter is approximately between 10 and 30 minutes, and the endurance range of a COTS fixed wing drone aircraft is approximately between 30 minutes and 2 hours. To scan a large coverage area, it is advantageous to efficiently design the flight path and/or terrestrial travel path to satisfy one or more endurance constraints of a given UAS platform. Such an efficiency plan is described herein as a mission metric optimization scheme.

Notable trajectory optimization algorithms can be divided into five general categories. The classical exact cellular decomposition algorithm generates a sweeping trajectory to cover an entire Area of Interest (AOI), which applies a zigzag route on discretized cells. This sweeping method may be computationally fast, but can be limited when an AOI is a non-convex shape, including, for example, a flat face of a built environment as shown in FIG. 5. To solve this limitation, it has been shown to be advantageous to apply decomposition techniques that divide an AOI into multiple convex areas. The representative decomposition methods can include, for example, trapezoidal, the boustrophedon, and Morse-based cellular decompositions.

The trapezoidal decomposition technique may be applied by creating multiple trapezoids or triangles that represent navigational features such as building envelope features using an extended vertical line at each vertex of the respective feature defined in the 3-D point cloud model. However, the drawback of this method is that it generates many small sub-areas. This method may require use of an additional function that merges small areas to reduce the number of sub-areas. To mitigate this issue, boustrophedon decomposition has been introduced, which decomposes a scanning area using critical vertices. The Boustrophedon method may, in some instances, have a limitation when it has non-polygon restricted areas or obstacles inside of an AOI. The Morse-based cellular decomposition method efficiently solves the non-polygon restricted area issue through generating a relatively smooth scanning trajectory depending on the selection of a Morse function.

An alternative grid-based method may utilize a wavefront-based algorithm, which is a well-known coverage trajectory technique in the field of robotics. In some aspects, the coverage path planning system 107 may apply this method by generating a wave propagation algorithm, and assigning numbers to each grid (not shown in FIG. 4) within an AOI based on initial/terminal positions and the information of restricted areas. Using the assigned numbers of each grid, the analytics module 105 may apply pseudo-gradient information (not shown in FIG. 5) to compute a complete coverage trajectory. The advantage of this method is that the coverage path planning system 107 may solve a non-convex AOI with a non-linear objective function. Hence, the coverage path planning system 107 may apply the wavefront-based algorithm to generate an optimum UAS scanning trajectory.

Another grid-based trajectory optimization method may include a vehicle routing-based approach that may solve an optimal route problem for vehicles from central depots to a set of customer locations. The vehicle routing problem typically solves a cost function minimizing total traveling distance/time subject to one or multiple depots, a set of vehicles, the locations of customers, and customers' demands. The vehicle routing approach has a flexible structure that enables one to efficiently manage design variables such as the number of vehicles, fixed/free depots, and a set of vehicle constraints. For instance, this vehicle routing problem-based trajectory optimization scheme has been applied to address the UAS coverage problem. Most of recent literature associated with a coverage path-planning algorithm is handling a 2-D terrain problem that generally assumes a flat surface. In other words, path-planning algorithms generate a complete scanning trajectory on Above Ground Level (AGL) that does not actually account for the shape of the ground surface. In agriculture robot applications, some conventional approaches have ignored elevation changes. However, this assumption may not be an ideal assumption for building envelope sensing because of the significant elevation impact. Such an assumption may imply that the coverage trajectory of an aerial image also needs to consider characteristics of the terrain topology.

Choi et al. proposed a three-dimensional UAS trajectory optimization algorithm for a remote sensing mission to capture the actual terrain's topological characteristics, which allows a more realistic coverage trajectory. The proposed method incorporates a Gaussian Process (GP)-based terrain modeling method and a distance-constrained vehicle routing problem. The terrain modeling process creates a terrain model using a GP-based on the information of a Digital Elevation Model (DEM). Then, using the GP terrain model, the proposed method determines UAS waypoints. Next, the scanning trajectory optimization solves a distance-constrained vehicle routing problem for an optimal scanning trajectory that must visit all the waypoints.

Another popular terrain modeling approach is Gaussian Process-based terrain modeling. The representative example of a GP-based terrain model employs a local approximation method using K-Dimensional (KD)-Trees for a scalable terrain model. According to an embodiment of the present disclosure, the coverage path planning system 107 may apply a Gaussian Process for a terrain model as a mission metric optimization scheme, which may be advantageous over GP-based terrain models to handle uncertainties. A GP as a non-parametric technique is a collection of random variables, which may have a finite number of subsets with a Gaussian distribution. The GP model can be represented by

f(x)˜GP(μ(x),k(x,\hat{x})),

where μ(x) is the mean function, and k(x, x\hat{ }) is the covariance function.

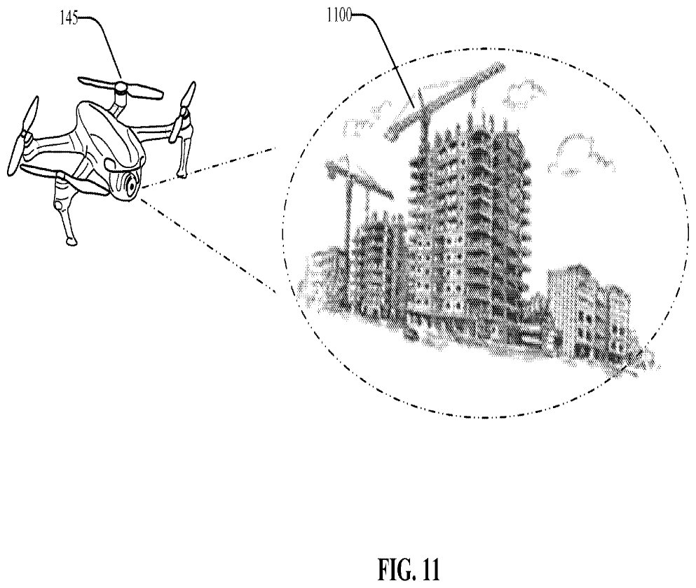

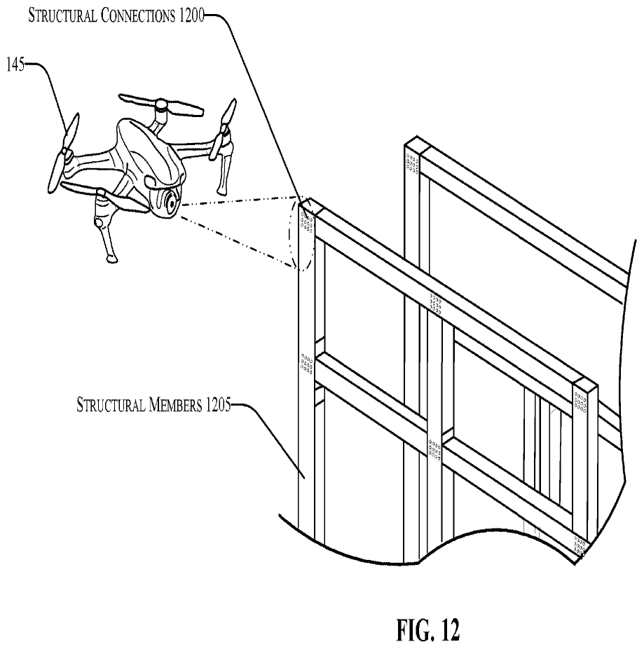

The energy modeling calibration for the energy model calibration system 100 (described with respect to FIG. 1) includes the remote deployable transient sensory system 145, which may be provided for contracted use to building managers for energy audits and inspection, which may produce data for generating the C²BEM 109. In other aspects, such as those described with respect to FIGS. 11 and 12, the energy model calibration system 100 may be further used for construction inspection and monitoring, to monitor site building progress, perform construction inspections, and obtain information usable for design compliance checking.

Starting first with an example of energy model calibration, FIG. 5 illustrates an exemplary collection of post-occupancy energy usage data associated with a building envelope 500 of a building envelope 505 using the remote deployable transient sensory system 145, according to embodiments of the present disclosure. In one embodiment, the remote deployable transient sensory system 145 may collect post-occupancy energy usage data at the building envelope 500. The remote deployable transient sensory system 145 may execute the optimized path 155, where the remote deployable transient sensory system 145 is deployed remotely from a home base (e.g., proximate to the building envelope 500 as shown in FIG. 5) for collection of post-occupancy energy usage data. The home base may be proximate to and/or be defined by the position of the ground station 205, as shown in FIG. 2.

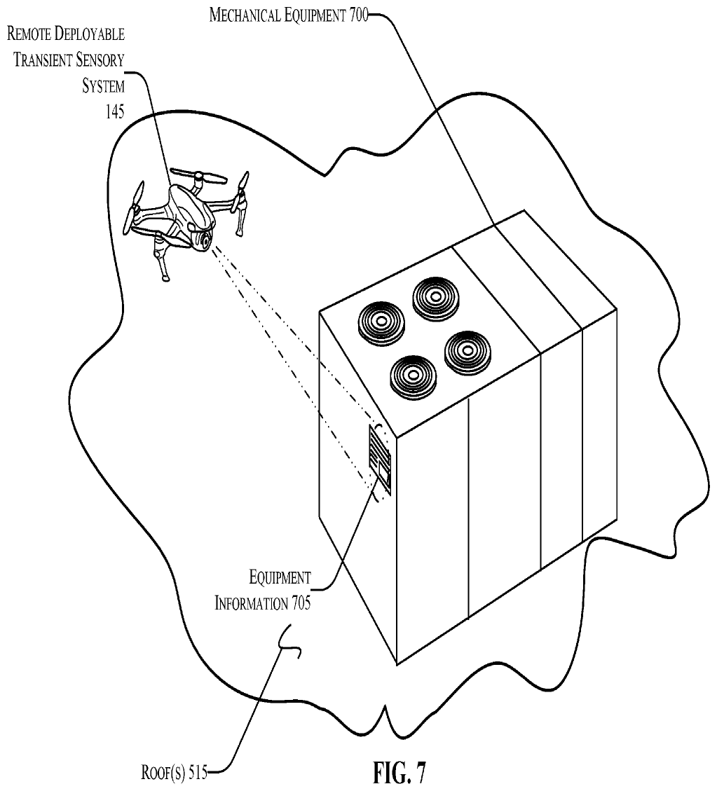

The building envelope 500 of the building envelope 505 can include, for example, one or more glazing elements 510, roof(s) 515, building facade elements 535, and one or more building fenestrations 525. As shown in FIGS. 6 and 7 hereinafter, the building envelope 505 may further include mechanical equipment 700 disposed on a rooftop surface. The building envelope 505 may also include one or more obstacles 520 disposed proximate to the building envelope 505, around which the remote deployable transient sensory system 145 may navigate autonomously while executing the flight path and/or terrestrial travel path 540.

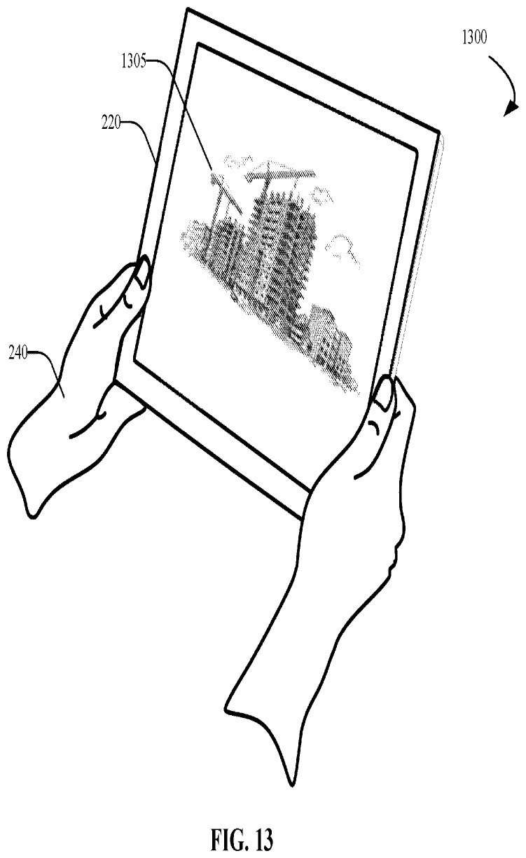

The building envelope 500 may include, for example, glazing elements 510, one or more roofs 515, building fenestrations 525, thermal sealing media 530, building facade elements 535, and/or other built environment characteristics not shown in FIG. 5. As described in greater detail with respect to FIG. 13, the remote deployable transient sensory system 145 may be deployable in the vicinity of the building envelope 505 as part of the remote deployable transient sensory kit 210 (hereafter “kit 210”), which may be sent via standard shipping from a data aggregator to a user 240 who may be, for example, a building owner or a facility manager. In some jurisdictions, such as the United States, when the remote deployable transient sensory system 145 is configured as a UAS, a Federal Aviation Administration (FAA) Part 107 certified drone pilot, or other individual certified by law, may be present or remotely monitor the flight(s) for the building owner or facility manager.

Nevertheless, apart from jurisdictional requirements, it should be appreciated that one benefit of the remote deployable transient sensory kit 210 can include the deployment of the remote deployable transient sensory system 145 without having any specialized knowledge of drone or autonomous system operation. For example, as shown in FIG. 5, the user 240 may deploy the remote deployable transient sensory system 145 from the remote deployable transient sensory kit 210 using the mobile device 220 containing the app interface, which may be a personal mobile device operated by the user 240, or a mobile device such as a tablet or laptop computer included as part of the remote deployable transient sensory kit 210.

In an illustrative embodiment, the user 240 may receive the remote deployable transient sensory kit 210 and place the remote deployable transient sensory kit 210 proximate to the building envelope 505 at a point specified in a set of instructions that may be included with the remote deployable transient sensory kit 210. The user 240 may deploy the remote deployable transient sensory system 145 directly from the kit by opening a lid of the kit (not shown in FIG. 5), switching the device(s) to an energized or “on” mode, and deploying the remote deployable transient sensory system 145 using the mobile device 220 using an interface (not shown in FIG. 5) provided as an application on the mobile device. In some aspects, the remote deployable transient sensory system 145 may deploy by executing the path 155 (as shown in FIGS. 1 and 2) to follow a flight path and/or terrestrial travel path 540 that facilitates the remote deployable transient sensory system 145 as it traverses a series of waypoints 545 along the flight path and/or terrestrial travel path 540.

As shown in FIG. 5, and as observed in ordinary building scenarios, there may be obstacles 520 such as trees, light posts, vehicles, pedestrians, or other features that may not be part of the pre-planned and programmed optimized path 155. Accordingly, the remote deployable transient sensory system 145 may include autonomous operation features that cause the remote deployable transient sensory system 145 to avoid collision with such obstacles 520 by traversing, avoiding, or landing at a safe position until such time as traversal of the building envelope may be safe and navigable. After initialization and launch of the remote deployable transient sensory system 145, the system may begin its flight/terrestrial mission according to the optimized path 155.

FIG. 6 depicts another view of the flight path and/or terrestrial travel path 540 after deployment by the user 240 during a use case where the energy model calibration system 100 is configured for calibration and optimization of the C² BEM 109. The remote deployable transient sensory system 145 may traverse airspace to the first waypoint of a plurality of waypoints 545. In embodiments (not shown in FIG. 6) where the remote deployable transient sensory system 145 includes a ground-based drone, the flight path and/or terrestrial travel path 540 may be a ground-based travel path. As shown in the example of FIG. 6, a waypoint may be localized proximate to the building envelope 505 at glazing elements 510, or some other building envelope feature. One benefit of the remote deployable transient sensory system 145, is that the remote deployable transient sensory system 145 provides accessibility for obtaining sensory data in difficult-to-reach areas of the building envelope 505, such as, for example the roofs 515, upper-story glazing elements 510, and/or mechanical equipment 700 (shown in FIG. 7). For example, the remote deployable transient sensory system 145 may navigate to one or more waypoints 545 which may be localized proximate to the building envelope 505. Accordingly, the remote deployable transient sensory system 145 may navigate from waypoint to waypoint as it investigates each respective instance of the building feature of interest. In the present example, the feature of interest may be the glazing elements 510 and/or thermal sealing media 530. Although the example of FIG. 6 depicts glazing elements 510 as the feature of interest, it should be appreciated that the feature of interest, which may be selected by human input to the energy model calibration system 100 and/or via automated analysis and prediction algorithm executed by the coverage path planning system 107, may include any number and combination of building envelope features. For example, there may be any number of building envelope features including features other than the example features discussed herein.

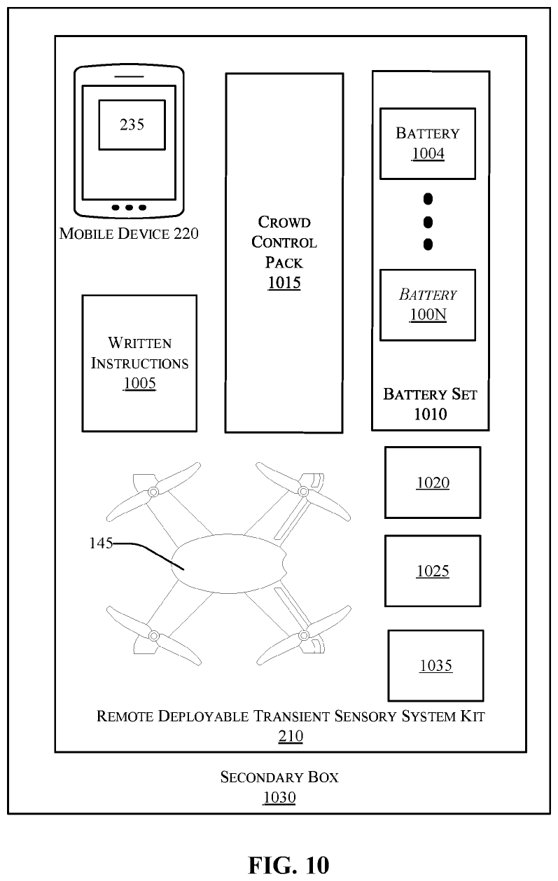

In one aspect, a user 240 may receive a remote deployable transient sensory kit 210 via traditional delivery methods (e.g., the postal service, courier, or package delivery service). The remote deployable transient sensory kit 210 (discussed with respect to FIG. 10) may include the remote deployable transient sensory system 145 and the mobile device 220, among other items. The mobile device 220 may be configured to receive sensory dataset(s) from the remote deployable transient sensory system 145 during or after the remote deployable transient sensory system 145 performs sensory operations on the building envelope 505 along a flight path and/or terrestrial travel path 540. During execution of the flight plan, the remote deployable transient sensory system 145 may navigate to a first waypoint of a plurality of waypoints 545, and navigate to approximate positions for each successive waypoint. Accordingly, the remote deployable transient sensory system 145 may navigate to relative positions for each instance of a built environment element of interest (e.g., the glazing elements 510 shown in FIG. 6 or another building envelope feature such as thermal sealing media 530, for example) to collect sensory data using infrared systems, LiDAR systems, photogrammetry, or other known methods for data collection.

After arrival at the first waypoint of the plurality of waypoints 545, the remote deployable transient sensory system 145 may observe aspects of the feature of interest by maintaining its relative position to the feature of interest for a predetermined period of time (e.g., 1 second, 5 seconds, 10 seconds, etc.), before traversing along the flight path and/or terrestrial travel path 540 to the next waypoint. The method of traversing the waypoints may be specified according to the mission metric optimization scheme that aims to accomplish one or more flight metric objectives such as flight fuel usage minimization, flight time minimization, flight distance minimization, and/or flight trajectory change minimization.

While at a waypoint and maintaining its stationary position, the remote deployable transient sensory system 145 may utilize the VPS 281 (as shown in FIG. 2) to obtain sensory data readings associated with the plurality of building envelope features. The sensory data may indicate the presence or absence of energy inefficiencies such as air leakage, junction failures, mechanical fastener failures, misalignments, etc.

Although any number of functional defects are possible, which may not be disclosed herein, it should be appreciated that those skilled in the art of building energy efficiency inspection and energy modeling understand that there are many possible manifestations of inspectable criteria that may be observable using the VPS 281. For example, the remote deployable transient sensory system 145 may utilize an RGB imaging device to determine presence of cracking or degradation of sealant media associated with thermal sealing media 530, verified with simultaneous infrared imagery of some RGB features.

In another example, the remote deployable transient sensory system 145 may utilize an infrared camera to determine heat signatures associated with energy entry or exit around one or more glazing elements 510.

In yet another example, the remote deployable transient sensory system 145 may utilize a sonar sensor system to determine relative shapes, dimensions, proximity, or other features associated with building envelope features. In another example, the remote deployable transient sensory system 145 may traverse a set of waypoints (not shown in FIG. 6) that lead the remote deployable transient sensory system 145 around the periphery of the building envelope 500 along the roof line, which may indicate energy leakage associated with the roofline connection with the building facade elements 535.

In yet another example, the remote deployable transient sensory system 145 may traverse the waypoints 545 and inspect the condition of the building facade elements 535 to determine whether the elements are securely fastened, in working condition within defined tolerances, and sealed at appropriate junctions such that underlying insulating materials are not being degraded by the elements. The remote deployable transient sensory system 145 may obtain the sensory data readings associated with the plurality of building envelope features, individually, on a consecutive basis until each feature associated with the respective waypoint of the plurality of waypoints 545 is identified and the respective data is recorded in a computer readable memory of the remote deployable transient sensory system 145.

FIG. 7 illustrates collection of post-occupancy energy usage data associated with mechanical equipment 700 using the remote deployable transient sensory system 145, according to embodiments of the present disclosure. In one aspect, the remote deployable transient sensory system 145 may be configured with an onboard artificial intelligence (AI) engine that may navigate to a building feature of interest (e.g., the mechanical equipment 700), and determine a make, model, manufacture date, and other information associated with the building feature. For example, the remote deployable transient sensory system 145 may obtain sensory data indicative of equipment information 705 to determine a positive identification for the mechanical equipment 700. It may perform this step by identifying a marking, label, sign, or other insignia disposed on an exterior surface of the mechanical equipment 700, navigate itself to a position proximate to the location of the marking information, and observe the equipment information 705 using the RGB camera (not shown in FIG. 7) associated with the VPS 281. Accordingly, the remote deployable transient sensory system 145 may retrieve imagery indicative of the make and model of the mechanical equipment, perform an optical character recognition on the RGB image(s), and/or transmit that information to the server(s) 270 via the network 225. Transmitting the information may include transmitting the obtained RGB image as part of a sensory dataset, or may include transmitting an identification of the mechanical equipment 700 responsive to performing optical character recognition on the RGB image, accessing publicly-available information via a data link to the Internet, confirming that the mechanical equipment 700 matches the obtained publicly-available information (e.g., shape, dimensions, markings, features, etc.), and transmitting the make and model to the mobile device 220. In another embodiment, where the remote deployable transient sensory system 145 sends only an RGB image of the equipment information 705 to the receiving device (e.g., the mobile device 220, servers 270, etc.), and the receiving device performs the equipment lookup to obtain operational parameters that may indicate aspects of the functionality of the equipment. The receiving device may reference specifications for the mechanical equipment 700, and forward the specifications to the remote deployable transient sensory system 145. In one aspect, the remote deployable transient sensory system 145 may observe a function of the mechanical equipment 700 to determine a status as to its general functionality.

In another embodiment, there may not be publicly available information associated with the mechanical equipment. One strength of the system disclosed herein can include the ability to cross-reference crowd sourced information associated with building energy efficiency, which may include building equipment utilized in connected infrastructure. According to embodiments described herein, crowd sourced information may include data originating from one or more built environments that was formerly or currently analyzed by JOULEA™. By leveraging crowd sourced information, JOULEA™ may optimize newly analyzed buildings with relatively compressed time frames as compared to a new building analysis not using crowd sourced information. One analogous example of crowd sourced information may include navigational applications that take in user inputs indicative of locations of road work, traffic speed traps, etc. such as Waze, and leverage the crowd sourced information for collective enrichment of the user base and application.

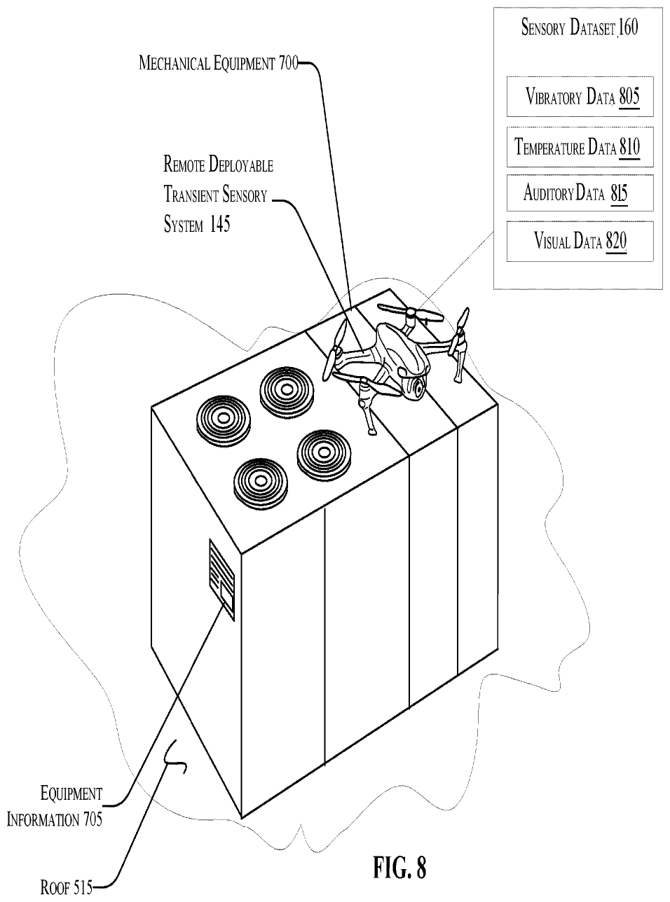

In some aspects, the energy model calibration system 100 may collect information associated with functionality of the mechanical equipment 700, create a dataset indicative of the functionality, and reference the dataset with information that may be correlated to indicate equipment functional characteristics associated with temperature, sound profiles (e.g., audible frequency content), vibrational frequency content, amplitude information, heat signatures, and other information. FIG. 8 depicts one embodiment where the remote deployable transient sensory system 145 obtains a sensory dataset that can include such information.

With reference now to FIG. 8, in one example embodiment where the remote deployable transient sensory system 145 is a UAS, the sensory system may position itself on a surface of the mechanical equipment 700, and disengage its rotors to reduce or eliminate background noise and vibration. The remote deployable transient sensory system 145 may then begin collecting a sensory dataset 160 that includes vibratory data 805, temperature data 810, auditory data 815, and/or visual data 820, while the mechanical equipment 700 is in operation. The sensory dataset 160 may provide operational information that can, when observed in connection with equipment functionality or fault detection, be used to identify fault detection characteristics exhibited by equipment installed in other buildings. Moreover, the sensory dataset 160 may be usable as a baseline point of comparison for subsequent periodic mechanical equipment checks, which may provide fault detection of equipment at a later date. For example, after the collection of the sensory dataset 160, that dataset may be compared with a second sensory dataset (not shown in FIG. 8) obtained thereafter during a similar procedure, where the comparison may indicate a change in the equipment functionality characteristics (e.g., vibration, temperature, sound, or visual data).

### Section III—BEM Data Collection Using a Remote Deployable Transient Sensory Kit

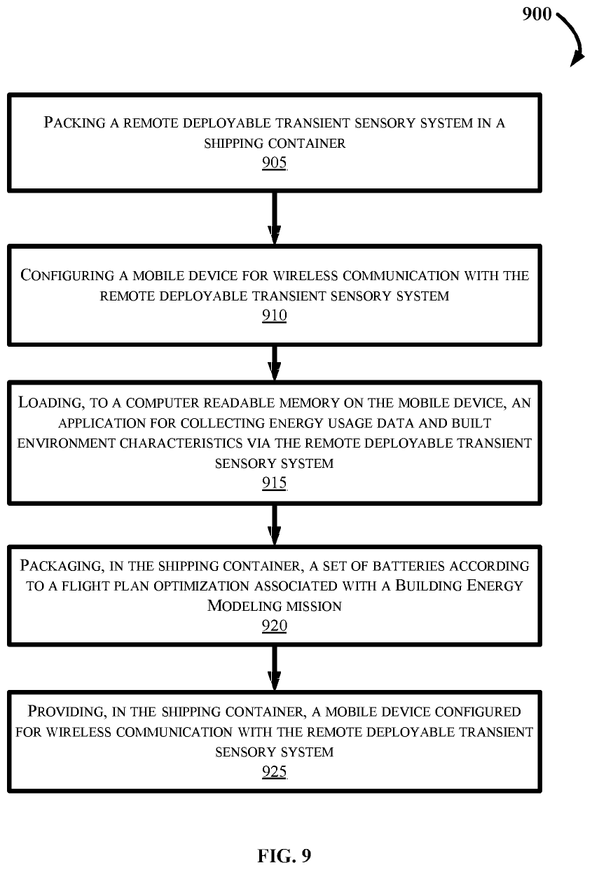

FIG. 9 is a flow diagram of an example method 900 for providing a remote deployable transient sensory kit 210 deployable for collecting sensory data, according to embodiments of the present disclosure. As explained in prior sections of this disclosure, it is advantageous to provide the remote deployable transient sensory kit 210 to building owners, managers, or other FAA Part 107 certified personnel such that they can receive the kit, position the remote deployable transient sensory kit 210 at a predetermined home base position proximate to the building envelope 500, and deploy the remote deployable transient sensory system 145 using the mobile device 220, which may be included with the remote deployable transient sensory kit 210 or be a mobile device associated with the user 240 (e.g., the user's privately-operated mobile device). In some aspects, the remote deployable transient sensory kit 210 may allow a non-professional user (e.g., a user having no prior skills or knowledge of operating autonomous aerial vehicles or other drones) to receive the remote deployable transient sensory kit 210, open the shipping container comprising the kit, install the app on the user's personal mobile device, if applicable, and deploy the remote deployable transient sensory system 145 after powering on the device(s) in the kit and following a set of instructions that may be included in the remote deployable transient sensory kit 210 in paper or electronic format.

At step 905 the method 900 includes packing a remote deployable transient sensory system in a shipping container. Although the shape and form of the shipping container may vary, it should be appreciated that the shipping container used to ship the remote deployable transient sensory kit 210 may include an exterior box (e.g., a secondary box 1030 as shown in FIG. 10) that is separate from the remote deployable transient sensory kit 210. In one embodiment the secondary box 1030 may be integrated as part of the remote deployable transient sensory kit 210 such that the secondary box is the outermost box and also the housing for the remote deployable transient sensory kit 210, where the secondary box 1030 includes a rigid exterior structure (such as, for example, a hinged rigid box having a lid, a latch, a lock mechanism, etc.).

At step 910, the method 900 may include configuring a mobile device (e.g., the mobile device 220) for wireless communication with the remote deployable transient sensory system 145. The wireless communication may take place via direct connection between the mobile device 220 and the remote deployable transient sensory system 145, and/or via the network 225 as discussed with respect to FIG. 2.

At step 915, the method 900 may include loading, to a computer readable memory on the mobile device (e.g., the memory 221 as shown in FIG. 2), an application (e.g., the application 235) for collecting energy usage data and built environment characteristics such as volume or gross floor area via the remote deployable transient sensory system 145.

At step 920, the method 900 may include packaging, in the shipping container, a set of batteries according to a flight plan optimization associated with the building energy modeling mission. The set of batteries may include one or more batteries having, collectively, charge sufficient for performing the missions associated with the optimized path 155. In some aspects, the optimized path 155 may include a single flight, where the footprint and height of the building being analyzed are sized such that a single flight/terrestrial mission using a single battery is within a threshold of error for energy usage required to complete the flight/terrestrial mission. In another aspect, a larger built environment may require a longer expected flight time due to its size, the number of building characteristics to be sensed during the mission(s), and other factors such as weather, known energy usage rates in flight, etc. Accordingly, providing multiple batteries may include determining a number of flight/terrestrial missions needed to complete a building energy survey, determining a flight length in time for each of the one or more flight/terrestrial missions, and determining the number of battery units to be included in the remote deployable transient sensory kit 210. The number of batteries to be included can be further based on an expected charge time for recharging the batteries. For example, it may be advantageous to provide a battery count that provides for 4 to 5 battery changes during a preplanned flight/terrestrial mission, where the remote deployable transient sensory system 145 determines that an operational battery is approaching a fully discharged state, returns to the home base proximate to the built environment, and the user 240 replaces the discharged battery with one or more of the set of batteries included with the remote deployable transient sensory kit 210, while charging any discharged battery using a power receptacle or using a recharging pack (not shown in FIG. 2) that may be included with the remote deployable transient sensory kit 210..

At step 925, the method 900 may include providing, in the shipping container, the mobile device 220, where the mobile device 220 is configured for wireless communication with the remote deployable transient sensory system 145. The mobile device 220 may be a mobile phone, a smart phone, a laptop, a tablet, or another handheld device as described with respect to FIG. 2.

FIG. 10 illustrates an example remote deployable transient sensory kit 210 according to embodiments of the present disclosure. The remote deployable transient sensory kit 210 may include the mobile device 220, the remote deployable transient sensory system 145, a set of written instructions 1005, a battery set 1010, a crowd control pack 1015, a launch platform 1035, which may include a table, platform or other collapsible structure, a return authorization label 1020 that may be used to fund shipment of the remote deployable transient sensory kit 210 back to the data aggregator (e.g., the owner of the remote deployable transient sensory kit 210), and packing tape 1025 that may be used to seal a secondary box 1030 for returning the remote deployable transient sensory kit 210 via package carrier services associated with the return authorization label 1020.

The crowd control pack 1015 may include “do not cross” tape that may be used to control pedestrian traffic while the remote deployable transient sensory system 145 is in use. Other devices may be included in the crowd control pack 1015 including, for example, flashing warning lights, a light control mechanism such as a wireless light controller (not shown in FIG. 10), extendable telescoping poles for holding the Caution Do Not Enter tape, traffic cones, warning signs, etc., or other means and methods.

The written instructions 1005 may be included in the remote deployable transient sensory kit 210, where the instructions inform the user 240 of a starting location or home base position from which the remote deployable transient sensory system 145 should be deployed, instructions for powering on and off the equipment, instructions for changing the batteries during one or more flight/terrestrial missions, and instructions for repackaging and returning the remote deployable transient sensory kit 210 to the sender after completion of the mission. In other aspects, the instructions may be included in electronic form loaded on the mobile device 220, such that a user may power the mobile device 220 on, and the instruction set is displayed immediately after powering on the device.

The remote deployable transient sensory kit 210 may provide a seamless end-to-end building energy modeling solution for users such as building owners, managers, etc., to identify energy efficiency issues associated with a built environment without knowledge of energy modeling or autonomous vehicle operation. The process of using the remote deployable transient sensory kit 210 may begin with use of a geo-accurate satellite service to plan the client's first flight path and terrestrial drone path.

The modeler may receive one or more customer inputs to identify an ideal position on the property of the built environment to serve as home base for the drone during the flight(s) and terrestrial drone data capture—this includes consideration for avoiding any private property that may be contiguous to the building/property.

The modeler or machine learning engine 108 may use a weather tool to forecast date(s) and time window(s) for drone deployment according to predicted weather conditions. This may include determining times and dates that may have a low likelihood for atmospheric conditions that may not be conducive to drone deployment such as high wind, inclement weather, etc.

The system may also calculate the flight and ground trajectories that may be used to gather LiDAR, RADAR, SONAR, RGB & thermal data during deployment, including appropriate gimbal angles, offsets, and ground sampling distances. Flight and ground trajectories are stored as simulations on the JOULEA™ platform and linked to the customer's account for customer viewing.

The remote deployable transient sensory kit 210 may be assembled in accordance with the built environment such as square footage and other factors such as anticipated foot traffic. These factors may inform aspects of the kit contents, such as a number of charged batteries, and the quantity of crowd control features such as safety cones. The kit may be further equipped with standard items and equipment such as a charging station, a charge controller and cable, a mobile device (tablet) and charging cable, a home base landing pad, one or more SD cards, and the prepaid return shipping label.

Once assembled, the remote deployable transient sensory kit 210 may be shipped directly to the user. After receiving the kit through common carrier and logistics, the user logs into the application using the mobile device (e.g., a mobile app on an iPad or other mobile device), the app may guide the user or the client representative (e.g., if a certified FAA Part 107 drone pilot is operating the procedure) through a pre-flight checklist and flight preparation as known in the art of drone operation.

The user may access a trajectory algorithm via the mobile app and activate the flight/terrestrial mission via a secure token. The secure token may transmit information to the cloud-connected system so that the JOULEA™ client team is aware of the impending drone data capture, and the team may follow the flight/terrestrial mission and be available should the client need any real-time assistance.

The mobile app communicates with the drone(s) via an onboard computer that is installed on the drone(s) to create a dependable communication loop from the app to the drone. The client representative or FAA Part 107 certified pilot may use the mobile app to start the trajectory. The app runs the entire flight and ground trajectory either as the entire built environment's area of interest or segmented by façade elevation for the ease of following FAA Part 107 safety protocols. The mobile app also tracks the drone(s)' battery usage and brings the drone(s) back to the home base landing pad when batteries need to be changed. If the mission plan for the client's building requires a high number of waypoints, the mobile app will prompt the client or FAA Part 107 certified drone pilot to charge the batteries during the flight for re-use.

The drone may send all data captured from aerial and/or terrestrial trajectory to JOULEA™ via a wireless link through the Internet. Onboard SD card(s) may provide backup access to data when faults occur with the wireless link.

The client or FAA Part 107 certified drone pilot may complete the drone data capture mission, and send the remote deployable transient sensory kit 210 back to the sending team (e.g., JOULEA™) using the enclosed prepaid return shipping label and the outer box.

The LiDAR, RADAR, SONAR, RGB & thermal data captured during the autonomous trajectory may be sent via the Internet, and/or stored on the drones' SD card(s). The data are downloaded and wiped from the SD card(s) once the drone(s) has/have been received by the JOULEA™ team.

LiDAR, RADAR, SONAR, RGB & thermal data captured during the autonomous trajectory are processed by the JOULEA™ modeler or machine learning engine 108 to produce a calibrated building energy model of the built environment in question that is accessible to the client via the JOULEA™ platform.

Once the drone data capture is complete and the drone(s) is/are with the JOULEA™ team, a second package containing Sensors in a Box will be shipped to the customer. This package will contain a set of wireless occupancy, humidity, temperature, HVAC, lighting, plug load, water usage and other easy-to-install mechanical, electrical and plumbing system monitoring and environmental sensors that will capture and transmit data within the built environment to the JOULEA™ platform. The sensors may be sent to the building management team with detailed instructions for installation throughout their building.

The kit data may inform the continuously calibrated engine for the most updated C² BEM 109 for the given built environment, as well as the general data link for use by the JOULEA™ machine learning algorithm for optimization of the calibrated energy model. When a sensor sends faults to the JOULEA™ platform, the platform will detect this and ship a replacement sensor to the client along with a prepaid return shipping package to send back the faulty sensor. Upon receipt of the faulty sensor, the JOULEA™ team may run diagnostic tests, tune and possibly subsequently redeploy the sensor(s) to a built environment.

Once the calibrated energy model optimization is complete, the platform's online dashboard presents benchmarking along with the client built environment energy usage, carbon footprint and other relevant data (i.e. temperature, occupancy, relative humidity, etc.). A report about the building is also generated and the client's dashboard offers the owner and/or facility management suggestions as well as ownership level capital expenditures planning recommendations for suggested upgrades in order to decrease energy usage and carbon footprint.

Additional drone aerial and terrestrial trajectories are undertaken as needed (monthly, quarterly, semiannually, or yearly) in order to maintain a continuous record and time lapse comparison. All data is stored within the client's account on the JOULEA™ platform.

### Section IV—Design Compliance Using a Remote Deployable Transient Sensory Kit

As explained in earlier sections, the remote deployable transient sensory kit 210 may be utilized in various ways, including sending a pre-programmed autonomous drone system to a user for the purpose of creation of the C² BEM 109. In another embodiment, the remote deployable transient sensory kit 210 may be configured and sent to a user responsible for monitoring a construction project. FIG. 11 illustrates the collection of built environment construction data associated with a build site using the remote deployable transient sensory kit 210, according to embodiments of the present disclosure.

As shown in FIG. 11, the remote deployable transient sensory system 145 may observe construction projects for the purpose of construction inspection and monitoring related to design compliance for post-occupancy energy usage. In one aspect, the remote deployable transient sensory system 145 may be sent as part of the remote deployable transient sensory kit 210 to a construction site such as the site 1100 depicted in FIG. 11. The remote deployable transient sensory system 145 may utilize the VPS 281 to observe and monitor the build site 1100 using RGB, thermal, LiDAR, RADAR, SONAR, etc. In one embodiment, the home base may be a location proximate to the build site 1100 such that the remote deployable transient sensory system 145 may fly to predetermined waypoints (waypoints not shown in FIG. 11) to capture datasets associated with the construction of the build site 1100.

Monitoring the build site 1100 may differ from the embodiments described with respect to FIGS. 5-8 in that monitoring the build site 1100 is expected to take a relatively longer duration of time due to construction schedules as compared with executing flight plans to capture datasets for creation of the C² BEM 109, which may include data associated with a post-occupancy built environment. For example, the build site 1100, having multiple large structures, may take many months to complete. In one aspect, the remote deployable transient sensory kit 210 may be sent to the build site, and deployed remotely via the user 240 such that the remote deployable transient sensory system 145 captures construction data over time using imagery and other sensory equipment. In one example, the remote deployable transient sensory system 145 may use the VPS 281, and more specifically, RGB, thermal, LiDAR, RADAR, SONAR, etc., to create a time lapse record of construction progress over the course of the project by capturing sensor data of the build site 1100 from the same vantage points incrementally (e.g., days, weeks, months, etc.).

In another example, the remote deployable transient sensory system 145 may utilize the VPS 281 to check for design compliance that can include compliance to design specifications that may affect building energy efficiency, as well as general engineering compliance during construction for features such as plumbing, electrical and mechanical location. In one example, checking for design compliance may include observing localization and thicknesses for thermal bridging features. In another example, the remote deployable transient sensory system 145 may observe a location for placement of plumbing and/or electrical infrastructure that may be buried underground after the initial build using the TCU 260 to record GPS coordinates for elements of the observed build steps. In another example, monitoring design compliance may include glazing installation features that may affect thermal conductivity, sealant inspection, and/or other similar features. Accordingly, the remote deployable transient sensory system 145 may localize the construction elements, and compare the location, size, or other features of the construction elements to design data that may be uploaded to the memory 255.

In another example, the remote deployable transient sensory system 145 may check for design compliance using onboard equipment in locations that are otherwise difficult to reach during the construction process. FIG. 12 depicts the collection of building construction data associated with a build site using the remote deployable transient sensory system 145, according to embodiments of the present disclosure. The remote deployable transient sensory system 145 is depicted in flight and observing structural connections in order to mitigate the risk of thermal bridging within the structural components post-occupancy, the structural connections 1200 may include, for example, welds, bolts, nuts, steel structure tie-ins and reinforcements into concrete and/or other structural connections. The remote deployable transient sensory system 145 may observe a count of the structural connections 1200, location of the structural connections 1200, placement pattern, or other characteristics that may be identified in design drawings. In another aspect, the remote deployable transient sensory system 145 may observe a structural member configuration for one or more structural members 1205, to ensure design plan compliance with respect to the structural members used, the number of members, insulation at the members and connecting means for the members, all in order to mitigate the risk of thermal bridging within the structural components post-occupancy. Other aspects are possible, and such aspects are contemplated. It should be appreciated that by using the remote deployable transient sensory system 145, structural connections located in otherwise difficult to reach locations may be monitored, sensed, and documented as compliant for the mitigation of thermal bridging.

In another example, the remote deployable transient sensory system 145 may fly to locations of structural member connections to observe and investigate the condition of welded joints and insulation prior to completion of the structural frame of a building in order to mitigate the risk of thermal bridging amongst the structural components post-occupancy.

When used for architectural and mechanical, electrical and plumbing engineering design compliance monitoring, building envelope construction monitoring may inform the client about sources of energy inefficiency using thermographic imaging. For example, the remote deployable transient sensory system 145 may be configured to capture building envelope energy inefficiency issues such as window installation errors, gaps in glazing media, window fabrication errors such as argon gas leakage in the window set, or other types of issues that may be determined using thermographic imagery. The machine learning engine 108, which may be loaded to the memory 255 onboard the ground station 205, may determine that a data anomaly indicates the presence of a building envelope malfunction that may be responsible for energy inefficiency.

In one example, the remote deployable transient sensory system 145 may discover a window having leaks or no insulating gas (e.g., argon, air, etc.) using infrared (IR) imagery to determine that a particular window has a temperature profile that is different than other installed windows in the building.

FIG. 13 depicts a user interface 1300 displaying output 1305 of a build site (e.g., the building site 1100 as shown in FIG. 11) based on the building construction data received from the remote deployable transient sensory system 145, according to embodiments of the present disclosure. In some aspects, the mobile device 220 may be usable to observe real-time imagery of the build site 1100, and/or include options for viewing time lapse photography of aspects of the project.

FIG. 14 depicts a block diagram of an example controller 1400 for the remote deployable transient sensory system 145, in accordance with embodiments. The controller 1400 may include an object collision avoidance system 1410 disposed in communication with a mobility control module 1405. The object collision avoidance system 1410 may perform object detection, navigation, and provide navigational interactive control features. The mobility control module 1405 may be configured and/or programmed to receive data from the object collision avoidance system 1410 to provide vehicle control.

The controller 1400 may be disposed in communication with and/or include the calibrated energy model calibration system 100, in accordance with embodiments described herein.

The mobility control module 1405 may include one or more processor(s) 1450, and a memory 1455. The processor(s) 1450 may be one or more commercially available general-purpose processor(s), such as a processor from the Intel® or ARM® architecture families. In some aspects, the mobility control module 1405 may be implemented in a system on a chip (SoC) configuration, to include other system components such as RAM, flash storage and I/O buses. Alternatively, mobility control module 1405 can be implemented using purpose-built integrated circuits, or any other suitable technology now known or later developed.

The memory 1455 may include executable instructions implementing the basic functionality of the controller 1400 and a database of locations in a geographic area. For example, the mobility control module 1405 may connect with a drive wheel controller 1415. The drive wheel controller 1415 may communicate signals to one or more traction motor(s) 1420, which may embody a drive mechanism such as a brushless direct current (DC) motor, or another traction motor technology. The mobility control module 1405 may cause the drive wheel controller 1415 to transmit motive signals to the traction motor(s) 1420 and to the remote deployable transient sensory system 145.

The controller 1400 may further include an interface device 1425 having input and output surfaces (not shown in FIG. 14) for providing interactive access to users onboard the UAV (e.g., the remote deployable transient sensory system 145). For example, the interface device 1425 may include a touch screen interface surface configured and/or programmed to provide operational information such as power consumption information, battery health, battery level, etc. In some embodiments, the interface device 1425 may further provide control features for controlling other motive aspects of the remote deployable transient sensory system 145, such as braking, acceleration, etc.

The interface device 1425 may also communicate information to and from the navigation interface 1445, and/or be integral with the navigation interface 1445 such that they share a common touch screen interface. The interface device 1425, either alone or in conjunction with the navigation interface 1445, may provide control prompts such as “indicate a building envelope feature of interest”, and receive operator inputs such as, for example, “return to home base”.

The ground station 205 may be further configured and/or programmed to communicate information with other devices and vehicles using a wireless transmitter 1430. The wireless transmitter 1430 may communicate with one or more other vehicles in a vehicle fleet (not shown in FIG. 14) and/or a central routing computer (e.g., the server(s) 270 as described with respect to FIG. 2) using a wireless communication network such as, for example, the network(s) 225. The network(s) 225 may be the Internet, a private network, a cellular telephone provider's data network, or other network infrastructure such as, for example, a vehicle-to-vehicle communication network. An example of a vehicle-to-vehicle communication protocol may be, for example, a dedicated short-range communication (DSRC) protocol.

The controller 1400 may be disposed in communication with the network 225. The remote deployable transient sensory system 145 may communicate with one or more other autonomous drones in a fleet of vehicles in various ways, including via an indirect communication channel using the network(s) 225, and/or via any number of direct communication channels. In some embodiments, it may be advantageous to utilize a fleet of deployable transient sensory systems that are substantially similar or identical to the remote deployable transient sensory system 145. This configuration of multiple coordinated systems may be advantageous when a built environment or construction project is larger in scale and requires multiple views of structurally complicated design features, and/or due to size, complexity, etc.

The object collision avoidance system 1410 may include one or more proximity sensor(s) 1435, one or more navigation receiver(s) 1440, and a navigation interface 1445 through which users of the controller 1400 may provide instructions or receive information about observed obstacles and building envelope characteristics of interest. The object collision avoidance system 1410 may communicate control signals to a mobile device application (e.g., the application(s) 235 described with respect to FIG. 2).

The object collision avoidance system 1410 may provide route management and communication between one or more other vehicles in the fleet, and to the operator of the vehicle. The mobility control module 1405 may receive navigational data from the navigation receiver(s) 1440 and the proximity sensor(s) 1435, determine a navigational path from a first location to a second location, and provide instructions to the drive wheel controller 1415 for autonomous, semi-autonomous, and/or manual operation.

The navigation receiver(s) 1440 can include one or more of a global positioning system (GPS) receiver, and/or other related satellite navigation systems such as the global navigation satellite system (GNSS), Galileo, or other similar systems known in the art of autonomous vehicle operation. Additionally, the navigation receiver(s) 1440 can be configured and/or programmed to receive locally based navigation cues to aid in precise navigation through space-restricted areas, such as, for example, in a crowded street, and/or in a distributed beacon environment. When deployed in conjunction with a distributed beacon network (not shown in FIG. 14), locally based navigation cues can include communication with one or more purpose-built location beacons (not shown in FIG. 14) placed throughout a geographic area. The navigation cues may enable an increased level of navigation precision and provide specific indicators for locations of various points of interest. In other aspects, the navigation receiver(s) 1440 may include one or more navigation transceivers (not shown in FIG. 14) for communication with mobile network infrastructure for cell tower triangulation and use of known-location Wi-Fi hotspots. Any location technology now known or later developed that can provide a high precision location (e.g., preferably within a linear foot) can be useful as part of navigation receiver(s) 1440. The navigation receiver(s) 1440 may operate in conjunction with instructions received from a path planning system 1485.

The proximity sensor(s) 1435 may alert the mobility control module 1405 to the presence of sensed obstacles, and provide trajectory information to the mobility control module 1405, where the trajectory information is indicative of moving objects or people that may interact with the remote deployable transient sensory system 145. The trajectory information may include one or more of a relative distance, a trajectory, a speed, a size approximation, a weight approximation, and/or other information that may indicate physical characteristics of a physical object or person.

Sensed obstacles can include other vehicles, pedestrians, animals, structures, curbs, and other random objects. In some implementations the proximity sensor(s) 1435 may be configured and/or programmed to determine the lateral dimensions of the path upon which the remote deployable transient sensory system 145 is traveling, e.g. determining relative distance from the side of a sidewalk or curb, to help aid the mobility control module 1405 in maintaining precise navigation on a particular path.

In the above disclosure, reference has been made to the accompanying drawings, which form a part hereof, which illustrate specific implementations in which the present disclosure may be practiced. It is understood that other implementations may be utilized, and structural changes may be made without departing from the scope of the present disclosure. References in the specification to “one embodiment,” “an embodiment,” “an example embodiment,” etc., indicate that the embodiment described may include a particular feature, structure, or characteristic, but every embodiment may not necessarily include the particular feature, structure, or characteristic. Moreover, such phrases are not necessarily referring to the same embodiment. Further, when a feature, structure, or characteristic is described in connection with an embodiment, one skilled in the art will recognize such feature, structure, or characteristic in connection with other embodiments whether or not explicitly described.

Further, where appropriate, the functions described herein can be performed in one or more of hardware, software, firmware, digital components, or analog components. For example, one or more application specific integrated circuits (ASICs) can be programmed to carry out one or more of the systems and procedures described herein. Certain terms are used throughout the description and claims refer to particular system components. As one skilled in the art will appreciate, components may be referred to by different names. This document does not intend to distinguish between components that differ in name, but not function.

It should also be understood that the word “example” as used herein is intended to be non-exclusionary and non-limiting in nature. More particularly, the word “example” as used herein indicates one among several examples, and it should be understood that no undue emphasis or preference is being directed to the particular example being described.

A computer-readable medium (also referred to as a processor-readable medium) includes any non-transitory (e.g., tangible) medium that participates in providing data (e.g., instructions) that may be read by a computer (e.g., by a processor of a computer). Such a medium may take many forms, including, but not limited to, non-volatile media and volatile media. Computing devices may include computer-executable instructions, where the instructions may be executable by one or more computing devices such as those listed above and stored on a computer-readable medium.

With regard to the processes, systems, methods, heuristics, etc. described herein, it should be understood that, although the steps of such processes, etc. have been described as occurring according to a certain ordered sequence, such processes could be practiced with the described steps performed in an order other than the order described herein. It further should be understood that certain steps could be performed simultaneously, that other steps could be added, or that certain steps described herein could be omitted. In other words, the descriptions of processes herein are provided for the purpose of illustrating various embodiments and should in no way be construed to limit the claims.

Accordingly, it is to be understood that the above description is intended to be illustrative and not restrictive. Many embodiments and applications other than the examples provided would be apparent upon reading the above description. The scope should be determined, not with reference to the above description, but should instead be determined with reference to the appended claims, along with the full scope of equivalents to which such claims are entitled. It is anticipated and intended that future developments will occur in the technologies discussed herein, and that the disclosed systems and methods will be incorporated into such future embodiments. In sum, it should be understood that the application is capable of modification and variation.

All terms used in the claims are intended to be given their ordinary meanings as understood by those knowledgeable in the technologies described herein unless an explicit indication to the contrary is made herein. In particular, use of the singular articles such as “a,” “the,” “said,” etc. should be read to recite one or more of the indicated elements unless a claim recites an explicit limitation to the contrary. Conditional language, such as, among others, “can,” “could,” “might,” or “may,” unless specifically stated otherwise, or otherwise understood within the context as used, is generally intended to convey that certain embodiments could include, while other embodiments may not include, certain features, elements, and/or steps. Thus, such conditional language is not generally intended to imply that features, elements, and/or steps are in any way required for one or more embodiments.

1. A method for providing a remote deployable transient sensory kit comprising:
providing a remote deployable transient sensory system in a shipping container;
configuring a mobile device for wireless communication with the remote deployable transient sensory system;
loading, to a computer readable memory on the mobile device, an application for collecting energy usage data and building characteristics via the remote deployable transient sensory system;
providing, in the shipping container, a set of batteries according to a flight plan optimization associated with a building energy modeling mission; and
providing, in the shipping container, a mobile device configured for wireless communication with the remote deployable transient sensory system.

2. The method according to claim 1, wherein the remote deployable transient sensory kit is configured to obtain a dataset usable to build a building energy model (BEM) that identifies a building envelope feature and a mitigation recommendation to reduce energy loss associated with an energy loss characteristic.

3. The method according to claim 1, further comprising:
sending the shipping container to a user via a package delivery service, wherein the remote deployable transient sensory kit is further configured for, after being received by the user, informing the user, via a set of written instructions disposed on an interior surface of the remote deployable transient sensory kit, for a procedure for deploying the remote deployable transient sensory system.

4. The method according to claim 3, wherein the set of written instructions provides instructions for:
receiving, via the mobile device, a user input that causes the remote deployable transient sensory system to deploy for a flight mission that generates a sensory dataset associated with a point cloud model.

5. The method according to claim 4, wherein the point cloud model comprises a 3-dimensional model representing a building envelope comprising:
data indicative of exterior surfaces of the building envelope; and
data that associates exterior surfaces of the building envelope with sensory data indicative of energy loss characteristics.

6. The method according to claim 3, wherein the set of written instructions provides instructions for:
receiving, via the mobile device, a user input that causes the remote deployable transient sensory system to deploy for a flight mission that generates a sensory dataset associated with a construction build site.

7. The method according to claim 1, further comprising:
providing a crowd control pack in the shipping container, wherein the crowd control pack comprises crowd control items for directing pedestrian traffic away from a flight area.

8. The method according to claim 1, wherein providing the set of batteries comprises:
receiving, from an analytics module, an optimized flight plan;
determining, based on the optimized flight plan, a number of flight missions associated with the optimized flight plan;
determining a time of flight associated with the optimized flight plan; and
providing the set of batteries, wherein the set of batteries comprise energy storage that exceeds a value associated with energy needed to power the remote deployable transient sensory system for the time of flight associated with the optimized flight plan.

9. A remote deployable transient sensory kit comprising:
a shipping container comprising:
a remote deployable transient sensory system comprising a controller;
a set of batteries configured according to a flight plan optimization associated with a building energy modeling mission; and
a mobile device for wireless communication with the remote deployable transient sensory system, the mobile device comprising:
a processor;
a computer-readable memory comprising an application executable via the processor for collecting energy usage data and building characteristics via the remote deployable transient sensory system; and
a transceiver configured for wireless communication with the remote deployable transient sensory system.

10. The remote deployable transient sensory kit according to claim 9, wherein the controller is programmed to execute instructions to:
obtain a dataset usable to build a building energy model (BEM) that identifies a building envelope feature and a mitigation recommendation to reduce energy loss associated with an energy loss characteristic.

11. The remote deployable transient sensory kit according to claim 9, further comprising a secondary box configured for sending the remote deployable transient sensory kit to a user via a package delivery service,
wherein the remote deployable transient sensory kit is further configured for, after being received by the user, informing the user, via a set of written instructions disposed on an interior surface of the remote deployable transient sensory kit, for a procedure for deploying the remote deployable transient sensory system.

12. The remote deployable transient sensory kit according to claim 11, wherein the set of written instructions, when executed, causes the processor to:
receive a user input that causes the remote deployable transient sensory system to deploy for a flight mission that generates a sensory dataset associated with a point cloud model.

13. The remote deployable transient sensory kit according to claim 12, wherein the point cloud model comprises a 3-dimensional model representing a building envelope comprising:
data indicative of exterior surfaces of the building envelope; and
data that associates exterior surfaces of the building envelope with sensory data indicative of energy loss characteristics.

14. The remote deployable transient sensory kit according to claim 11, wherein the set of written instructions, when executed, causes the processor to:
receive a user input that causes the remote deployable transient sensory system to deploy for a flight mission that generates a sensory dataset associated with a construction build site.

15. The remote deployable transient sensory kit according to claim 11, further comprising a crowd control pack, wherein the crowd control pack comprises crowd control items for directing pedestrian traffic away from a flight area.

16. The remote deployable transient sensory kit according to claim 11, wherein the set of batteries include a number of batteries based on an optimized flight plan;
wherein the number of batteries is based on a number of flight missions associated with the optimized flight plan;
determining a total time of flight associated with the optimized flight plan; and
wherein the set of batteries comprises energy storage that exceeds a value associated with energy needed to power the remote deployable transient sensory system for the total time of flight associated with the optimized flight plan.

17. A remote deployable transient sensory system associated with a remote deployable transient sensory kit, the remote deployable transient sensory system comprising:
a computer-readable memory comprising a flight plan instruction set;
a battery of a set of batteries, wherein the set of batteries comprises a number of batteries according to a flight plan optimization associated with a building energy modeling mission; and
a transceiver configured to communicate with a mobile device associated with the remote deployable transient sensory kit,
a controller disposed in communication with the computer-readable memory and the transceiver, wherein the controller is configured to:
receive a start command from the mobile device;
execute the flight plan instruction set responsive to receiving the start command; and
collect one or more of energy usage data and building characteristics data while in flight and using power received from the battery of the set of batteries; and
transmit, via the transceiver, a dataset comprising the one or more of energy usage data and building characteristics.

18. The remote deployable transient sensory system of claim 17, further comprising a flight control motor, wherein responsive to receiving the start command from the mobile device, the controller:
powers the flight control motor using power from the battery of the set of batteries;
commences a flight based on the flight plan instruction set;
generates a sensory dataset comprising the one or more of energy usage data and building characteristics data; and
transmits, via the transceiver, the one or more of energy usage data and building characteristics data to the mobile device.

19. The remote deployable transient sensory system of claim 17, wherein the start command causes the remote deployable transient sensory system to deploy for a flight mission that generates a sensory dataset associated with a construction build site.

20. The remote deployable transient sensory system of claim 17, wherein the start command causes the remote deployable transient sensory system to deploy for a flight mission that generates a dataset usable to build a building energy model (BEM) that identifies a building envelope feature and a mitigation recommendation to reduce energy loss associated with an energy loss characteristic.
